(19) United States
(12) Patent Application Publication
(10) Pub. No.: US 2022/0285440 A1
(43) Pub. Date: Sep. 8, 2022

(54) SEMICONDUCTOR STORAGE DEVICE

(71) Applicant: KIOXIA CORPORATION, Tokyo (JP)

(72) Inventors: Masahiro SHIMURA, Yokohama Kanagawa (JP); Takeshi YOSHIDA, Yokohama Kanagawa (JP)

(21) Appl. No.: 17/459,042

(22) Filed: Aug. 27, 2021

(30) Foreign Application Priority Data
Mar. 3, 2021 (JP) 2021-033948

(51) Int. Cl. H01L 27/24; H01L 27/11556; G11C 13/00; H01L 45/00

(52) U.S. Cl. CPC H01L 27/2454; H01L 27/11556; G11C 13/0002; H01L 45/1206

(57) ABSTRACT

A semiconductor storage device includes a substrate, a plurality of first conductive layers arranged along a first direction intersecting a surface of the substrate and extending along a second direction parallel to the surface, a semiconductor layer extending along the first direction and facing the plurality of first conductive layers in the second direction, a gate insulating film between the plurality of first conductive layers and the semiconductor layer, and a first resistance element extending along the first direction on or above the substrate. One end of the first resistance element in the first direction is closer in the first direction to the substrate than at least a part of the plurality of first conductive layers. The other end of the first resistance element in the first direction is farther in the first direction from the substrate than the plurality of first conductive layers.

### CROSS-REFERENCE TO RELATED APPLICATION

This application is based upon and claims the benefit of priority from Japanese Patent Application No. 2021-033948, filed Mar. 3, 2021, the entire contents of which are incorporated herein by reference.

### FIELD

Embodiments described herein relate generally to a semiconductor storage device.

### BACKGROUND

A semiconductor storage device may include a substrate and conductor layers arranged on the substrate in a first direction orthogonal to a surface of the substrate. A semiconductor pillar may extend along the first direction through the conductor layers, and a gate insulating film can be provided between the conductor layers and the semiconductor pillar. The gate insulating layer comprises a memory unit capable of storing data. The memory unit utilizes an insulating charge storage layer including silicon nitride (Si₃N₄) or a conductive charge storage layer such as a floating gate to store data.

### BRIEF DESCRIPTION OF THE DRAWINGS

FIG. 1 is a schematic circuit diagram of a semiconductor storage device according to a first embodiment.

FIG. 2 is a schematic plan view of a semiconductor storage device according to a first embodiment.

FIG. 3 through FIG. 7 are schematic cross-sectional views of a semiconductor storage device according to a first embodiment.

FIG. 8 through FIG. 32 depict a method of manufacturing a semiconductor storage device according to a first embodiment.

FIG. 33 is a schematic cross-sectional view of a semiconductor storage device according to a second embodiment.

FIG. 34 depicts a method of manufacturing a semiconductor storage device according to a second embodiment.

FIG. 35 is a schematic plan view of a semiconductor storage device according to a fourth embodiment.

FIG. 36 through FIG. 38 are schematic cross-sectional views of a semiconductor storage device according to a fourth embodiment.

FIG. 39 through FIG. 49 depict a method of manufacturing a semiconductor storage device according to a fourth embodiment.

FIG. 50 is a schematic cross-sectional view of a semiconductor storage device according to a fifth embodiment.

FIG. 51 and FIG. 52 depict a method of manufacturing a semiconductor storage device according to a fifth embodiment.

FIG. 53 is a schematic cross-sectional view of a semiconductor storage device according to a seventh embodiment.

FIG. 54 through FIG. 64 depict a method of manufacturing a semiconductor storage device according to a seventh embodiment.

FIG. 65 is a schematic cross-sectional view of a semiconductor storage device according to a modified example of a fifth embodiment.

FIG. 66 and FIG. 67 are schematic circuit diagrams of an application example of a resistance element.

### DETAILED DESCRIPTION

Embodiments provide a semiconductor storage device that can be easily integrated.

In general, according to one embodiment, a semiconductor storage device includes a substrate, a plurality of first conductive layers stacked on each other in a first direction intersecting a surface of the substrate and extending along a second direction parallel to the surface. A semiconductor layer extends in the first direction through the first conductive layers and faces each of first conductive layers in the second direction. A gate insulating film is between the semiconductor layer and the plurality of first conductive layers. A first resistance element on the substrate and extending in the first direction. One end of the first resistance element in the first direction is closer to the substrate than at least a part of the plurality of first conductive layers. The other end of the first resistance element in the first direction is farther from the substrate than the plurality of first conductive layers.

Next, semiconductor storage devices according to a plurality of embodiments will be described with reference to the drawings. The following embodiments are merely examples and are not intended to limit the present disclosure. The following drawings are schematic and some parts or structures and the like may be omitted for convenience of explanation. The same reference numerals may be given to parts common to a plurality of embodiments and the descriptions thereof may be omitted.

When the term “semiconductor storage device” is used in the present specification, the term may mean a memory die or a memory system including a controller die such as a memory chip, a memory card, or a solid-state drive (SSD). The term may also mean a host computer such as a smartphone, a tablet terminal, and a personal computer.

When the term “control circuit” is used in the present specification, the term may mean a peripheral circuit such as a sequencer provided on the memory die or may mean a controller die or a controller chip connected to the memory die, or a device that includes both.

In the present specification, when a first component is said to be “electrically connected” to a second component, the first component may be directly connected to the second component, or the first component may be connected to the second component via a wiring, a semiconductive member, a transistor, or the like. For example, when three transistors are connected in series, the first transistor can be said to be “electrically connected” to the third transistor even when the second transistor is in the OFF state.

In the present specification, when a first element is said to be “connected between” a second element and a third element, the phrase may mean that the first element, the second element, and the third element are connected in series and that the second element is connected to the third element via the first element.

In the present specification, when a circuit or the like is said to “conduct” two wirings or elements, the term may mean that the circuit (or the like) includes a transistor or switching element, and the transistor (or the like) is provided on a current path between the two wirings and that the transistor or the like has been turned on (made conductive) within the context of the description.

In the present specification, a direction parallel to the upper surface of the substrate is referred to as the X direction, a direction parallel to the upper surface of the substrate and perpendicular to the X direction is referred to as the Y direction, and a direction orthogonal to the upper surface of the substrate is referred to as the Z direction.

In the present specification, in some cases, a direction along a certain surface is referred to as a first direction, a direction intersecting the first direction along the surface is referred to as a second direction, and a direction intersecting the surface is referred to as a third direction. The first direction, the second direction, and the third direction may or may not correspond to any of the X direction, the Y direction, and the Z direction.

In the present specification, relative positional expressions such as “upper” and “lower” are generally used with reference to the direction orthogonal to the substrate. For example, the direction away from the substrate along the Z direction is referred to as upward, and the direction approaching the substrate along the Z direction is referred to as downward. When referring to a lower surface or a lower end of a certain element, use of “lower” means a surface or an end portion of the element on the side thereof closer to (and generally facing) the substrate, and when referring to an upper surface or an upper end of an element, use of “upper” means a surface or an end of the element on the side thereof farther from (and generally facing away from) the substrate. A surface of an element that intersects the X direction and/or the Y direction is referred to as a side surface or the like.

In the present specification, when referring to “width”, “length”, “thickness”, or the like in a direction in an element, a member, or the like, they may mean width, length, thickness, or the like in a cross section or the like observed by scanning electron microscopy (SEM), transmission electron microscopy (TEM), or the like.

In the present specification, when the term “radial direction” is used for a cylindrical or annular member or a through-via hole, the term means the direction of approaching the central axis in a plane perpendicular to the central axis of the cylinder or annulus or the direction away from the central axis in the plane. When the term “thickness in the radial direction” or the like is used, the term means the difference between the distance from the central axis to the inner peripheral surface and the distance from the central axis to the outer peripheral surface in such a plane.

### First Embodiment

[Circuit Configuration of Memory Die MD]

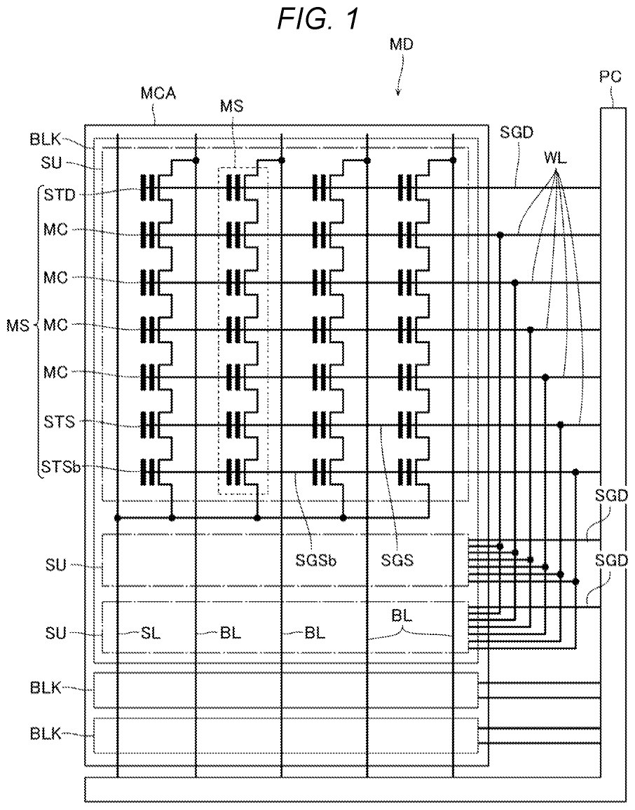

FIG. 1 is a schematic circuit diagram of a memory die MD. As shown in FIG. 1, the memory die MD includes a memory cell array MCA and a peripheral circuit PC.

As shown in FIG. 1, the memory cell array MCA includes a plurality of memory blocks BLK. Each of the plurality of memory blocks BLK includes a plurality of string units SU. Each of the plurality of string units SU includes a plurality of memory strings MS. One end of each of the plurality of memory strings MS is connected to the peripheral circuit PC via a bit line BL. The other end of each of the plurality of memory strings MS is connected to the peripheral circuit PC via a common source line SL.

Each memory string MS includes a drain-side select transistor STD, a plurality of memory cells MC (memory transistors), a source-side select transistor STS, and a source-side select transistor STSb. The drain-side select transistor STD, the plurality of memory cells MC, the source-side select transistor STS, and the source-side select transistor STSb are connected in series between the bit line BL and the source line SL. Hereinafter, the drain-side select transistor STD, the source-side select transistor STS, and the source-side select transistor STSb may be simply referred to as a select transistor (STD, STS, STSb).

Each memory cell MC is a field effect transistor. The memory cell MC includes a semiconductor layer, a gate insulating film, and a gate electrode. The semiconductor layer functions as a channel region. The gate insulating film includes a charge storage film. The threshold voltage of the memory cell MC changes according to the amount of charge in the charge storage film. The memory cell MC stores one-bit or multiple-bit data. A word line WL is connected to each of the gate electrodes of the plurality of memory cells MC corresponding to one memory string MS. Each of the word lines WL is commonly connected to all memory strings MS in one memory block BLK.

The select transistor (STD, STS, STSb) is a field effect transistor. The select transistor (STD, STS, STSb) includes a semiconductor layer, a gate insulating film, and a gate electrode. The semiconductor layer functions as a channel region. Select gate lines (SGD, SGS, SGSb) are connected to the gate electrodes of the select transistors (STD, STS, STSb), respectively. One drain-side select gate line SGD is commonly connected to all memory strings MS in one string unit SU. One source-side select gate line SGS is commonly connected to all memory strings MS in one memory block BLK. One source-side select gate line SGSb is commonly connected to all memory strings MS in one memory block BLK.

The peripheral circuit PC includes, for example, a voltage generation circuit that generates a plurality of operating voltages, a decoding circuit for applying the generated operating voltage to the bit line BL, the source line SL, the word line, and the select gate line (SGD, SGS, SGSb), a sense amplifier circuit for detecting the voltage or current of the bit line BL, and a sequencer for controlling the above-recited operations. The peripheral circuit PC includes a plurality of transistors, a plurality of capacitors, and a plurality of resistance elements that make up the above circuits.

[Structure of Memory Die MD]

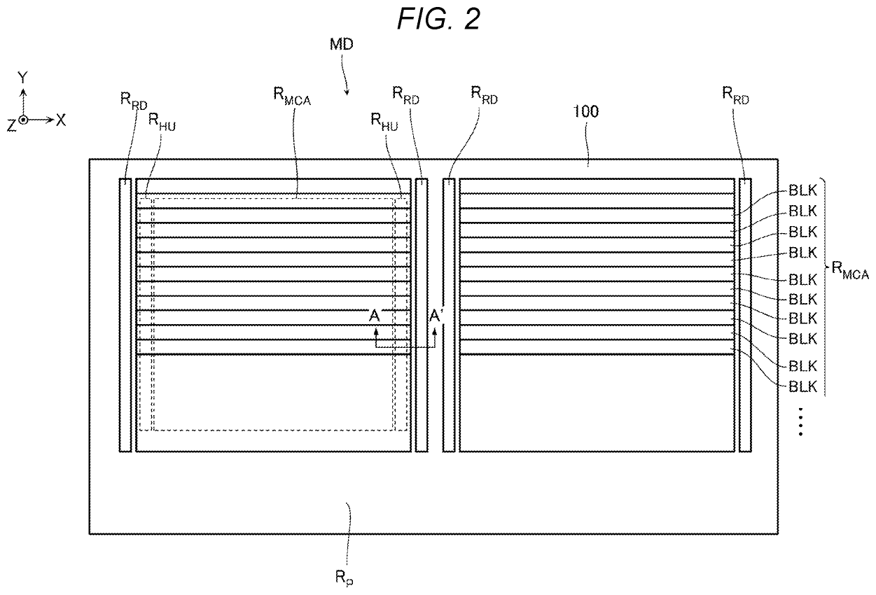

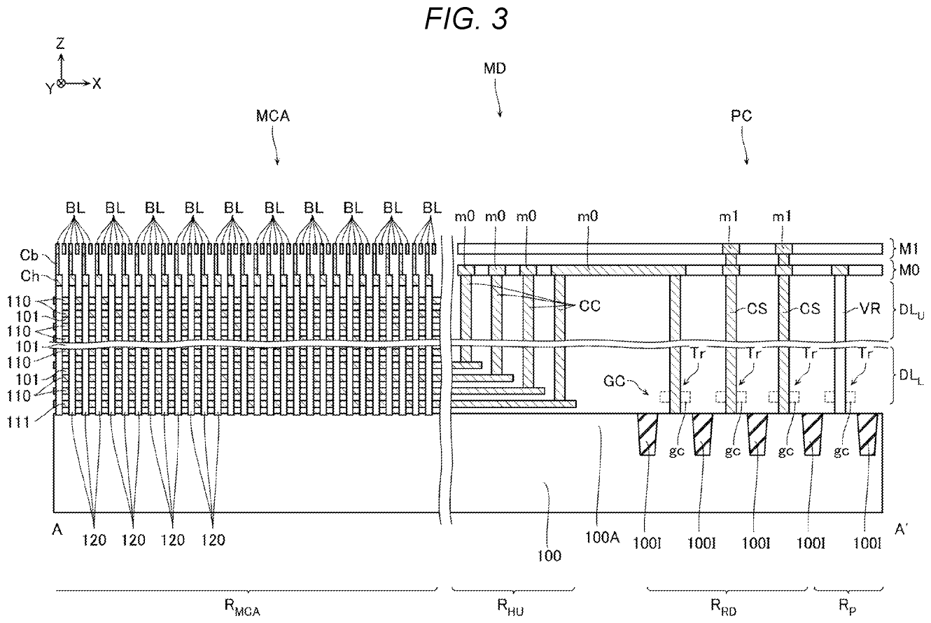

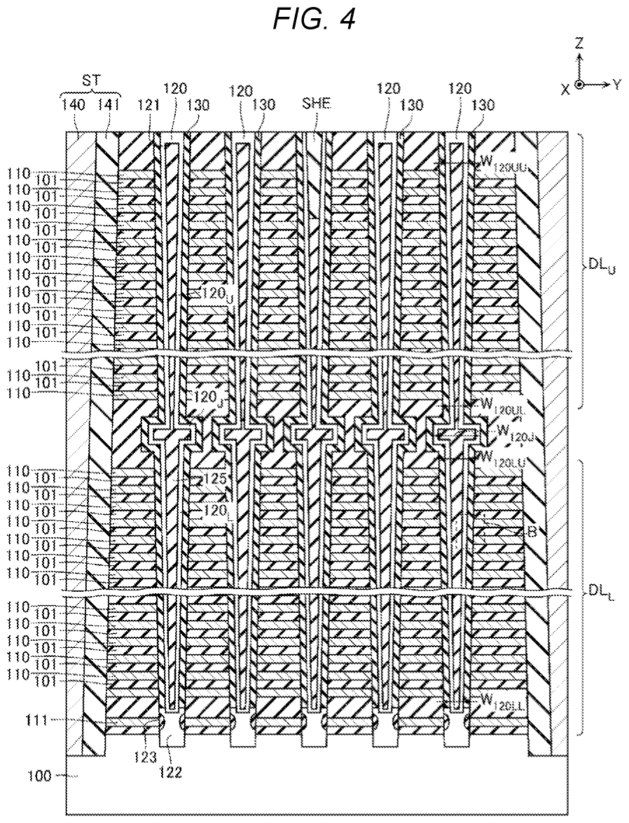

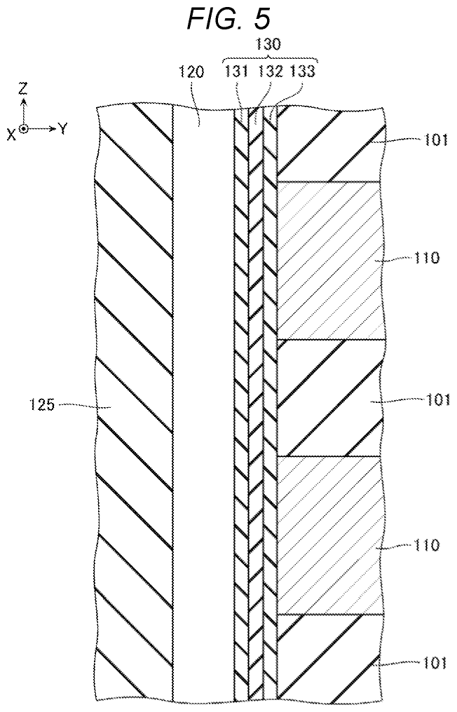

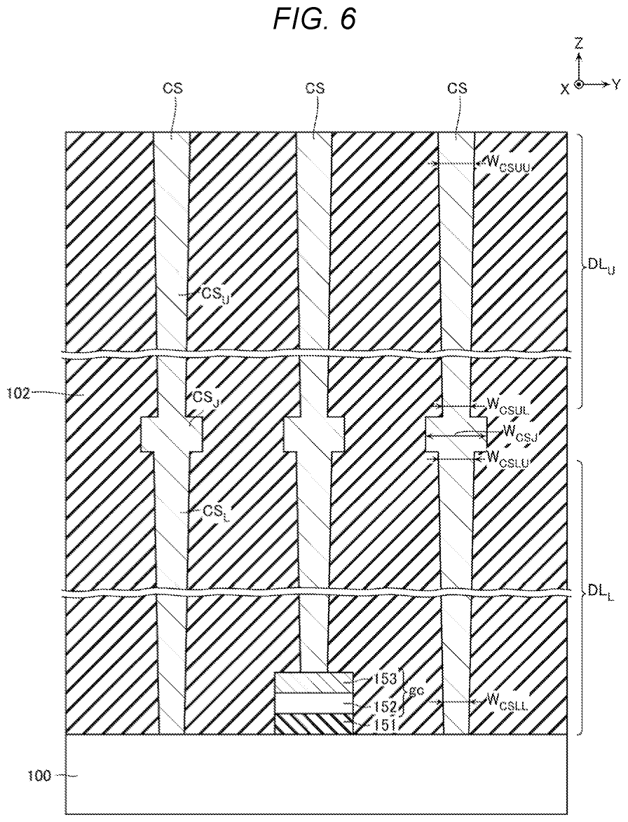

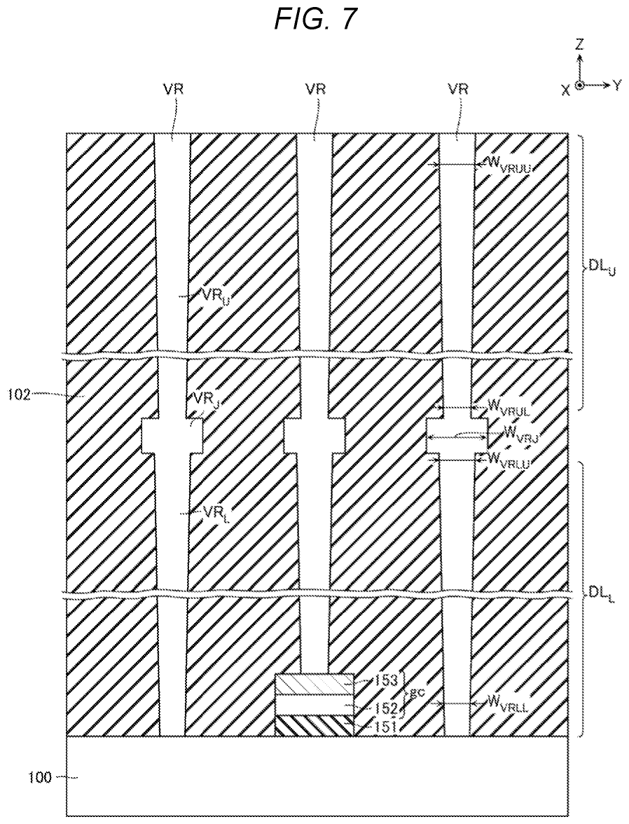

FIG. 2 is a schematic plan view of the memory die MD. FIG. 3 is a schematic cross-sectional view taken along the line A-A′ of the structure shown in FIG. 2 and viewed in the direction of the arrow. FIG. 4 is a schematic cross-sectional view of the memory die MD. FIG. 5 is a schematic enlarged view of the portion shown by B in FIG. 4. FIGS. 6 and 7 are schematic cross-sectional views of the memory die MD.

As shown in FIG. 2, the memory die MD includes a semiconductor substrate 100. In the illustrated example, the semiconductor substrate 100 includes two memory cell array regions R_{MCA} arranged along the X direction. A hookup region R_{HU} and a row decoder region R_{RD} farther from the memory cell array region R_{MCA} than the hookup region R_{HU} are provided at positions aligned with the memory cell array region R_{MCA} in the X direction. A peripheral circuit region Rₚ is provided in the other region of the semiconductor substrate 100.

As shown in FIG. 3, the memory die MD includes a device layer DL_{L} on the semiconductor substrate 100, a device layer DL_{U} above the device layer DL_{L}, a wiring layer M0 above the device layer DL_{U}, and a wiring layer M1 above the wiring layer M0.

[Structure of Semiconductor Substrate 100]

The semiconductor substrate 100 is, for example, a semiconductor substrate made of P-type silicon (Si) containing P-type impurities such as boron (B). For example, as shown in FIG. 3, an active region 100A and insulating regions 100I are provided on the surface of the semiconductor substrate 100. The active region 100A may be, for example, an N-type well region containing N-type impurities such as phosphorus (P), or a P-type well region containing P-type impurities such as boron (B), or a semiconductor substrate region in which an N-type well region and a P-type well region are not provided. The active region 100A functions as, for example, a plurality of transistors Tr and the like that make up the peripheral circuit PC. Each insulating region 100I includes, for example, an insulating layer such as silicon oxide (SiO₂)

[Structure of Device Layers DL_{L} and DL_{U} in Memory Cell Array Region R_{MCA}]

The memory cell array region R_{MCA} includes a plurality of memory blocks BLK arranged along the Y direction, for example, as shown in FIG. 2. An inter-block structure ST as shown in FIG. 4 is provided between two memory blocks BLK adjacent to each other in the Y direction.

As shown in FIG. 4, for example, each memory block BLK includes a plurality of conductive layers 110 arranged along the Z direction, a plurality of semiconductor layers 120 extending along the Z direction, and a plurality of gate insulating films 130 between the plurality of conductive layers 110 and the plurality of semiconductor layers 120.

The conductive layer 110 is a substantially plate-shaped conductive layer extending along the X direction. The conductive layer 110 may include a barrier conductive film such as titanium nitride (TiN) and a stacked film of a metal film such as tungsten (W). The conductive layer 110 may contain, for example, polycrystalline silicon containing impurities such as phosphorus (P) and boron (B). An insulating layer 101 such as silicon oxide (SiO₂) is provided between the plurality of conductive layers 110 arranged along the Z direction.

A conductive layer 111 is provided below the conductive layer 110. The conductive layer 111 may include, for example, a barrier conductive film such as titanium nitride (TiN) and a stacked film of a metal film such as tungsten (W). An insulating layer 101 such as silicon oxide (SiO₂) is provided between the conductive layer 111 and the conductive layer 110.

The conductive layer 111 functions as a gate electrode of the source-side select gate line SGSb (see FIG. 1) and the plurality of source-side select transistors STSb connected thereto. The conductive layer 111 of each memory blocks BLK is insulated from the others.

Among the plurality of conductive layers 110, one or more conductive layers 110 located at the lowest layer functions as a gate electrode of the source-side select gate line SGS (see FIG. 1) and the plurality of source-side select transistors STS connected thereto. Those conductive layers 110 of each memory block BLK is insulated from the others.

A plurality of conductive layers 110 located above the lowest layer function as gate electrodes of the word lines WL (see FIG. 1) and the plurality of memory cells MC (see FIG. 1) connected thereto. Each of the plurality of conductive layers 110 is electrically connected to the plurality of conductive layers 110 adjacent to each other in the Y direction. Those conductive layers 110 of each memory block BLK are insulated from the others.

One or more conductive layers 110 located further above function as a gate electrode of the drain-side select gate line SGD and the plurality of drain-side select transistors STD (see FIG. 1) connected thereto. The width of those conductive layers 110 in the Y direction is smaller than the other conductive layers 110. For example, as shown in FIG. 4, an insulating layer SHE between string units is provided between two conductive layers 110 adjacent to each other in the Y direction. Those conductive layers 110 of each string unit SU are insulated from the others.

The semiconductor layers 120 are arranged in a predetermined pattern along the X direction and the Y direction. Each semiconductor layer 120 functions as a channel region of a plurality of memory cells MC and select transistors (STD, STS, STSb) in one memory string MS (see FIG. 1). The semiconductor layer 120 is, for example, a semiconductor layer such as polycrystalline silicon (Si). The semiconductor layer 120 has a substantially cylindrical shape, and an insulating layer 125 such as silicon oxide is provided at a central portion thereof.

Each semiconductor layer 120 includes a semiconductor region 120_{L} in the device layer DL_{L} and a semiconductor region 120_{U} in the device layer DL_{U}. The semiconductor layer 120 includes a semiconductor region 120_{J} connected to the upper end of the semiconductor region 120_{L} and the lower end of the semiconductor region 120_{U}, and an impurity region 121 connected to the upper end of the semiconductor region 120_{U}. A semiconductor layer 122 is connected to the lower end of each semiconductor layer 120.

The semiconductor region 120_{L} is a substantially cylindrical region extending along the Z direction. The outer peripheral surface of the semiconductor region 120_{L} is surrounded by a plurality of conductive layers 110 in the device layer DL_{L} and faces the plurality of conductive layers 110. The radial width W_{120LL} of the lower end portion of the semiconductor region 120_{L} (for example, the portion located below the plurality of conductive layers 110 in the device layer DL_{L}) is smaller than the radial width W_{120LU} of the upper end portion of the semiconductor region 120_{L} (for example, the portion located above the plurality of conductive layers 110 in the device layer DL_{L}).

The semiconductor region 120_{U} is a substantially cylindrical region extending along the Z direction. The outer peripheral surface of the semiconductor region 120_{U} is surrounded by a plurality of conductive layers 110 in the device layer DL_{U} and faces the plurality of conductive layers 110. The radial width W_{120UL} of the lower end portion of the semiconductor region 120_{U} (for example, the portion located below the plurality of conductive layers 110 in the device layer DL_{U}) is smaller than the radial width W_{120UU} of the upper end portion of the semiconductor region 120_{U} (for example, the portion located above the plurality of conductive layers 110 in the device layer DL_{U}) and the above-described width W_{120LU}.

Each semiconductor region 120_{J} is provided above the plurality of conductive layers 110 in the device layer DL_{L} and is provided below the plurality of conductive layers 110 in the device layer DL_{U}. The radial width W_{120J} of the semiconductor region 120_{J} is larger than the widths W_{120LU} and W_{120UU}.

Each impurity region 121 contains N-type impurities such as phosphorus (P). The impurity region 121 is connected to the bit line BL via a via contact electrode Ch and a via contact electrode Cb (see FIG. 3).

Each semiconductor layer 122 is connected to the active region 100A of the semiconductor substrate 100. The semiconductor layer 122 is made of, for example, single crystal silicon (Si) or the like. The semiconductor layer 122 functions as a channel region of the source-side select transistor STSb. The outer peripheral surface of the semiconductor layer 122 is surrounded by the conductive layer 111 and faces the conductive layer 111. An insulating layer 123 such as silicon oxide is provided between the semiconductor layer 122 and the conductive layer 111.

Each gate insulating film 130 has a substantially cylindrical shape that covers the outer peripheral surface of the corresponding semiconductor layer 120.

As shown in FIG. 5, for example, the gate insulating film 130 includes a tunnel insulating film 131, a charge storage film 132, and a block insulating film 133, which are stacked between the semiconductor layer 120 and the conductive layer 110. The tunnel insulating film 131 and the block insulating film 133 are, for example, insulating films made of, for example, silicon oxide (SiO₂) . The charge storage film 132 is, for example, a film capable of storing charges and made of, for example, silicon nitride (Si₃N₄). Each of the tunnel insulating film 131, the charge storage film 132, and the block insulating film 133 has a substantially cylindrical shape and extends along the Z direction along the outer peripheral surface of the semiconductor layer 120.

FIG. 5 shows an example of the gate insulating film 130 including the charge storage film 132 made of silicon nitride. However, the gate insulating film 130 may include, for example, a floating gate made of polycrystalline silicon containing N-type or P-type impurities.

As shown in FIG. 4, for example, the inter-block structure ST includes a conductive layer 140 extending along the Z direction and the X direction, and an insulating layer 141 on the side surface of the conductive layer 140. The conductive layer 140 is connected to an N-type impurity region in the active region 100A of the semiconductor substrate 100. The conductive layer 140 may include, for example, a barrier conductive film made of, for example, titanium nitride (TiN) and a stacked metal film made of, for example, tungsten (W). The conductive layer 140 functions, for example, as a part of the source line SL (see FIG. 1).

[Structure of Device Layers DL_{L} and DL_{U} in Hookup Region R_{HU}]

As shown in FIG. 3, the hookup region REqu includes the end portions of a plurality of conductive layers 110 in the X direction. The end portions of the plurality of conductive layers 110 in the X direction are shifted in the X direction, thereby forming a substantially stepped shape. The hookup region REqu includes a plurality of via contact electrodes CC arranged along the X direction. Each of the plurality of via contact electrodes CC extends along the Z direction and is connected to the corresponding conductive layer 110 at the lower end of the via contact electrodes CC. The via contact electrode CC may include, for example, a barrier conductive film made of, for example, titanium nitride (TiN) and a stacked metal film made of, for example, tungsten (W).

[Structure of Device Layers DL_{L} and DL_{U} in Row Decoder Region R_{RD}]

As shown in FIG. 6, a wiring layer GC is provided on the semiconductor substrate 100 in the row decoder region R_{RD} (see FIG. 2). The wiring layer GC includes a plurality of electrodes gc facing the surface of the semiconductor substrate 100 across an insulating layer 151. The plurality of electrodes gc in the active region 100A of the semiconductor substrate 100 and the wiring layer GC are each connected to a via contact electrode CS.

The active region 100A of the semiconductor substrate 100 functions as a channel region of a plurality of transistors Tr that make up the peripheral circuit PC, one electrode of a plurality of capacitors, and the like.

The plurality of electrodes gc in the wiring layer GC function as gate electrodes of the plurality of transistors Tr that make up the peripheral circuit PC, the other electrodes of the plurality of capacitors, and the like. As shown in FIG. 6, for example, the electrode gc includes a semiconductor layer 152 made of, for example, silicon (Si) containing N-type impurities or P-type impurities, and a conductive layer 153 containing a metal such as tungsten (W). For example, as shown in FIG. 3, the upper surface of the electrode gc is located below at least a part of the plurality of conductive layers 110 in the device layer DL_{L}.

Each via contact electrode CS extends along the Z direction. The lower end of the via contact electrode CS is connected to the active region 100A of the semiconductor substrate 100 or the upper surface of the electrode gc. An impurity region containing N-type impurities or P-type impurities is provided at the connection portion between the via contact electrode CS and the active region 100A of the semiconductor substrate 100. The upper end of the via contact electrode CS is connected to the wiring m0. The via contact electrode CS may include, for example, a barrier conductive film made of, for example, titanium nitride (TiN) and a stacked metal film made of, for example, tungsten (W).

The via contact electrode CS includes a conductor region CS_{L} in the device layer DL_{L} and a conductor region CS_{U} in the device layer DL_{U}. The via contact electrode CS includes a conductor region CS_{J} connected to the upper end of the conductor region CS_{L} and the lower end of the conductor region CS_{U}.

The conductor region CS_{L} is a substantially columnar region extending along the Z direction. The outer peripheral surface of the conductor region CS_{L} is surrounded by an insulating layer 102 made of, for example, silicon oxide (SiO₂) contained in the device layer DL_{L}. The radial width W_{CSLL} of the lower end portion of the conductor region CS_{L} is smaller than the radial width W_{CSLU} of the upper end portion of the conductor region CS_{L} (for example, the portion located above the plurality of conductive layers 110 in the device layer DL_{L}). The lower end portion of the conductor region CS_{L} connected to the semiconductor substrate 100 may be, for example, a portion located below the plurality of conductive layers 110 in the device layer DL_{L}. The lower end portion of the conductor region CS_{L} connected to the electrode gc may be, for example, a connection portion with the electrode gc.

The conductor region CS_{U} is a substantially columnar region extending along the Z direction. The outer peripheral surface of the conductor region CS_{U} is surrounded by the insulating layer 102 in the device layer DL_{U}. The radial width W_{CSUL} of the lower end portion of the conductor region CS_{U} (for example, the portion located below the plurality of conductive layers 110 in the device layer DL_{U}) is smaller than the radial width W_{CSUU} of the upper end portion of the conductor region CS_{U} (for example, the portion located above the plurality of conductive layers 110 in the device layer DL_{U}) and the above-described width W_{CSUU}.

Each conductor region CS_{J} is provided above the plurality of conductive layers 110 in the device layer DL_{L} and is provided below the plurality of conductive layers 110 in the device layer DL_{U}. The radial width W_{CSJ} of the conductor region CS_{J} is larger than the above-described widths W_{CSLU} and W_{CSUU}.

[Structure of Device Layers DL_{L} and DL_{U} in Peripheral Circuit Region R_{P}]

The peripheral circuit region R_{P} of FIG. 2 includes the wiring layer GC on the substrate 100 via the insulating layer 151 (see FIG. 7). The peripheral circuit region R_{P} includes the plurality of via contact electrodes CS described above and a plurality of via resistors VR (see FIG. 7). The plurality of via resistors VR function as resistance elements that form a part of the peripheral circuit PC.

Each via resistor VR extends along the Z direction, for example, as shown in FIG. 7. The lower end of the via resistor VR is connected to the active region 100A of the semiconductor substrate 100 or the upper surface of the electrode gc. The upper end of the via resistor VR is connected to the wiring m0. The via resistor VR may include, for example, a semiconductor layer made of, for example, silicon (Si) containing N-type impurities or P-type impurities.

The via resistor VR includes a resistor region VR_{L} in the device layer DL_{L} and a resistor region VR_{U} in the device layer DL_{U}. The via resistor VR includes a resistor region VR_{J} connected to the upper end of the resistor region VR_{L} and the lower end of the resistor region VR_{U}.

The resistor region VR_{L} is a substantially columnar region extending along the Z direction. The outer peripheral surface of the resistor region VR_{L} is surrounded by the insulating layer 102 in the device layer DL_{L}. The radial width W_{VRLL} of the lower end portion of the resistor region VR_{L} is smaller than the radial width W_{VRLU} of the upper end portion of the resistor region VR_{L} (for example, the portion located above the plurality of conductive layers 110 in the device layer DL_{L}). The lower end portion of the resistor region VR_{L} connected to the semiconductor substrate 100 may be, for example, a portion located below the plurality of conductive layers 110 in the device layer DL_{L}. The lower end portion of the resistor region VR_{L} connected to the electrode gc may be, for example, a connection portion with the electrode gc.

The resistor region VR_{U} is a substantially columnar region extending along the Z direction. The outer peripheral surface of the resistor region VR_{U} is surrounded by the insulating layer 102 in the device layer DL_{U}. The radial width W_{VRUL} of the lower end portion of the resistor region VR_{U} (for example, the portion located below the plurality of conductive layers 110 in the device layer DL_{U}) is smaller than the radial width W_{VRUU} of the upper end portion of the resistor region VR_{U} (for example, the portion located above the plurality of conductive layers 110 in the device layer DL_{U}) and the above-described width W_{VRLU}.

Each resistor region VR_{J} is provided above the plurality of conductive layers 110 in the device layer DL_{L} and is provided below the plurality of conductive layers 110 in the device layer DL_{U}. The radial width W_{VRJ} of the resistor region VR_{J} is larger than the above-described widths W_{VRLU} and W_{VRUU}.

[Structure of Wiring Layers M0 and M1]

For example, as shown in FIG. 3, a plurality of wirings in the wiring layers M0 and M1 is connected to the respective semiconductor layers 120 via, for example, the via contact electrodes Cb and Ch described above. A plurality of wirings is connected to the respective conductive layers 110 via, for example, the via contact electrodes CC described above. A plurality of wirings is connected to the active region 100A of the semiconductor substrate 100 or the respective electrodes gc via, for example, the via contact electrodes CS or the via resistors VR described above.

The wiring layer M0 includes a plurality of wirings m0. Each of the plurality of wirings m0 may include, for example, a barrier conductive film made of, for example, titanium nitride (TiN) and a stacked metal film made of, for example, such as tungsten (W).

The wiring layer M1 includes a plurality of wirings m1. Each of the plurality of wirings m1 may include, for example, a barrier conductive film made of, for example, titanium nitride (TiN) and a stacked metal film made of, for example, copper (Cu). Some of the plurality of wirings m1 function as bit lines BL (see FIG. 1). Those bit lines BL are aligned along the X direction and extend along the Y direction.

[Manufacturing Method]

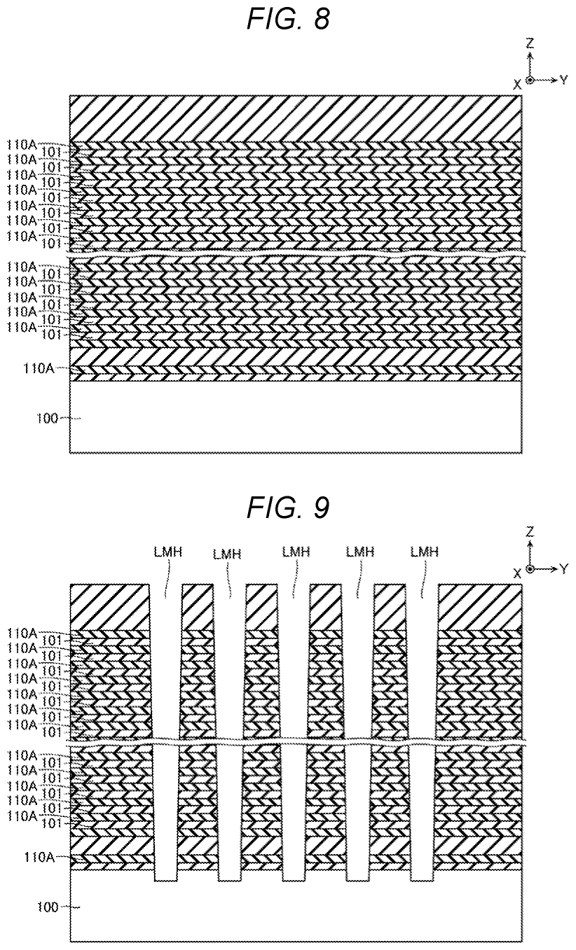

Next, a manufacturing method of the memory die MD will be described with reference to FIGS. 8 to 32. FIGS. 8 to 32 depict schematic cross-sectional views of the memory die MD for illustrating the manufacturing method. FIGS. 8 to 13 and 20 to 28 show cross sections corresponding to FIG. 4. FIGS. 14 to 19 and 29 to 31 show cross sections corresponding to FIG. 6. FIG. 32 shows a cross section corresponding to FIG. 7.

In manufacturing the memory die MD according to the present embodiment, first, the wiring layer GC is formed in the row decoder region R_{RD} and the peripheral circuit region R_{P} of the semiconductor substrate 100.

Next, for example, as shown in FIG. 8, the plurality of insulating layers 110A and 101 are formed on the semiconductor substrate 100. The insulating layer 110A is made of, for example, silicon nitride (SiN) or the like. The process is performed by, for example, a method such as chemical vapor deposition (CVD). The plurality of insulating layers 110A and 101 are formed in the memory cell array region R_{MCA} and the hookup region R_{HU} described with reference to FIG. 2. In the process, the insulating layer 102 is formed in the row decoder region R_{RD} and the peripheral circuit region R_{P} (see FIG. 14).

Next, for example, as shown in FIG. 9, a plurality of memory holes LMH are formed at positions corresponding to the semiconductor layers 120. Each memory hole LMH is a through via hole that extends along the Z direction, penetrates the insulating layers 101 and the insulating layers 110A, and exposes the upper surface of the semiconductor substrate 100. The process is performed by, for example, a method such as reactive ion etching (RIE).

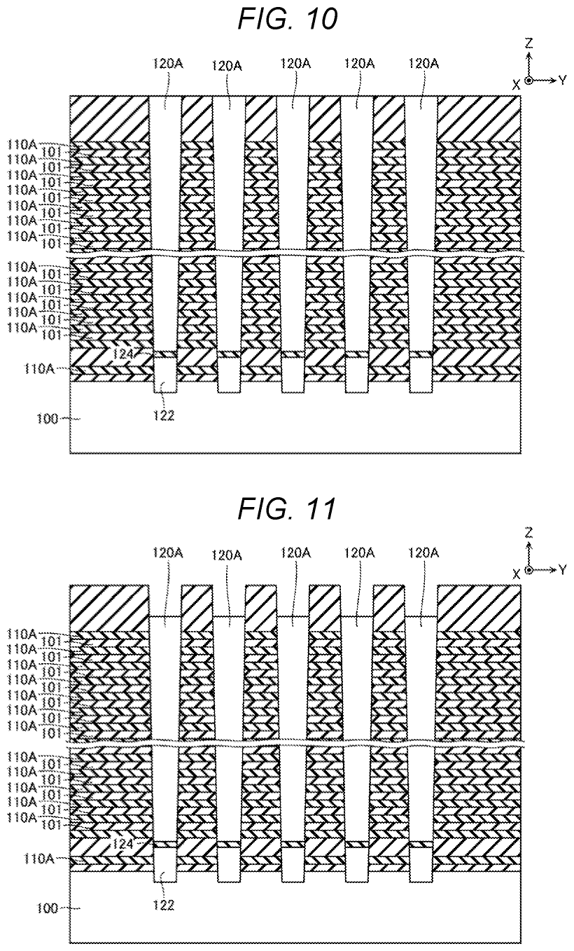

Next, for example, as shown in FIG. 10, the semiconductor layers 122 are formed on the bottom surface of the memory hole LMH. The process is performed by, for example, a method such as epitaxial growth.

Next, for example, as shown in FIG. 10, an insulating layer 124 is formed on the upper surface of each semiconductor layer 122. The process is performed by, for example, a method such as an oxidation treatment.

Next, for example, as shown in FIG. 10, an amorphous silicon film 120A is formed inside each memory hole LMH. The process is performed by, for example, a method such as CVD.

Next, for example, as shown in FIG. 11, the upper end portion of each amorphous silicon film 120A is removed. The process is performed by, for example, a method such as dry etching.

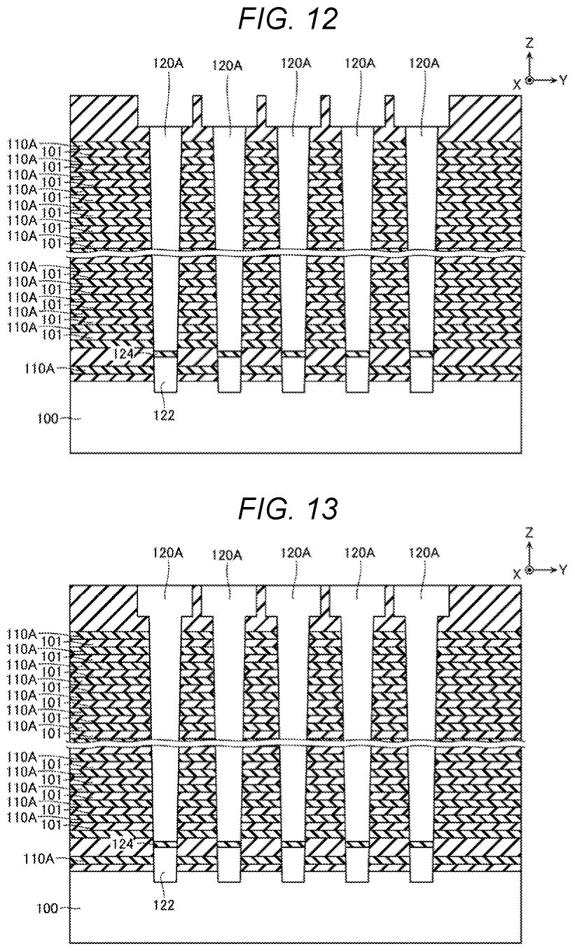

Next, for example, as shown in FIG. 12, a part of the insulating layer 102 around each memory hole LMH is removed. The process is performed by, for example, a method such as wet etching.

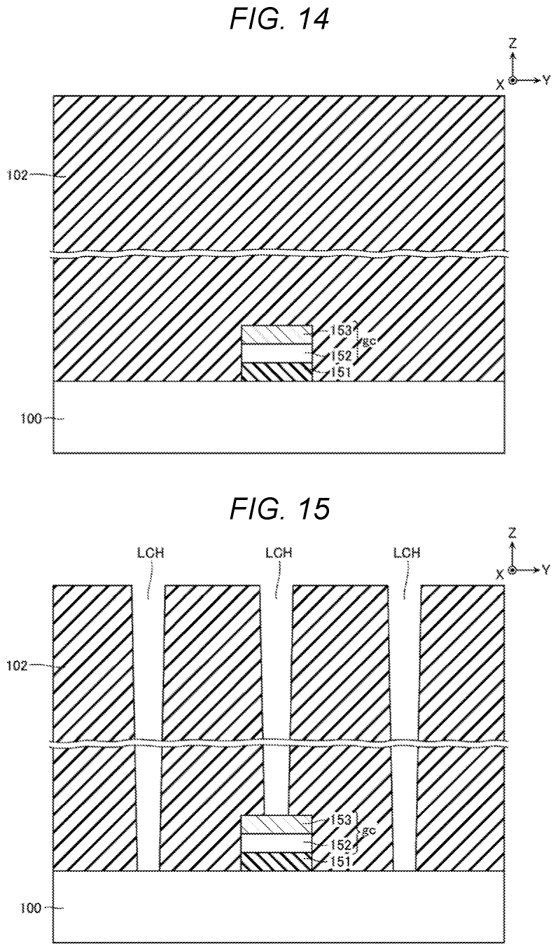

Next, for example, as shown in FIG. 13, another amorphous silicon film 120A is formed in each of portions from which the part of the insulating layer 102 has been removed (that is, on the upper surface of each existing amorphous silicon film 120A). The process is performed by, for example, a method such as CVD.

Next, as shown in FIGS. 14 and 15, for example, a plurality of contact holes LCH are formed at positions corresponding to the via contact electrodes CS and the via resistors VR. Each contact hole LCH is a through via hole that extends along the Z direction, penetrates the insulating layer 102, and exposes the upper surface of the semiconductor substrate 100 or the upper surface of an electrode gc. The process is performed by, for example, a method such as RIE.

Next, for example, as shown in FIG. 16, an amorphous silicon film CSA is formed inside each contact hole LCH. The process is performed by, for example, a method such as CVD.

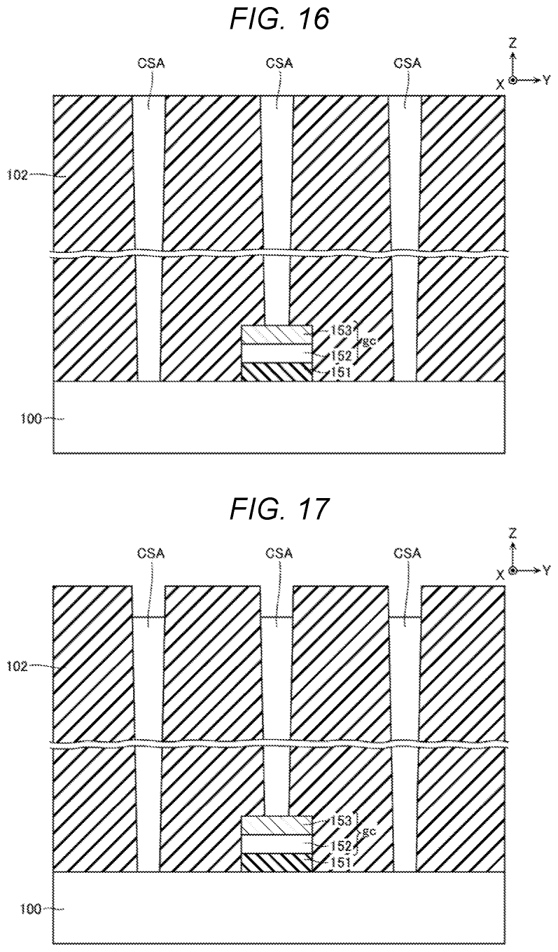

Next, for example, as shown in FIG. 17, the upper end portion of each amorphous silicon film CSA is removed. The process is performed by, for example, a method such as dry etching.

Next, for example, as shown in FIG. 18, a part of the insulating layer 102 around each contact hole LCH is removed. The process is performed by, for example, a method such as wet etching.

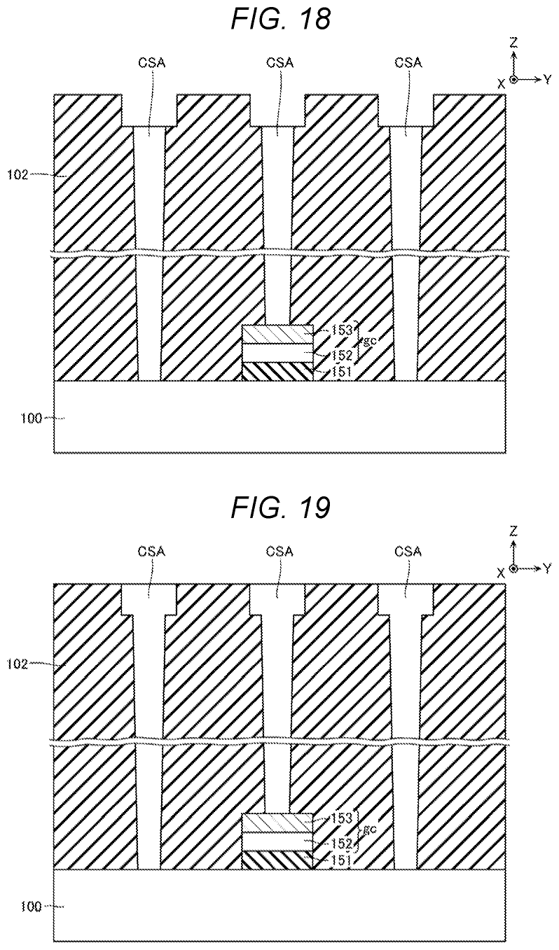

Next, for example, as shown in FIG. 19, another amorphous silicon film CSA is formed in each of portions from which the part of the insulating layer 102 has been removed (that is, on the upper surface of each existing amorphous silicon film CSA). The process is performed by, for example, a method such as CVD.

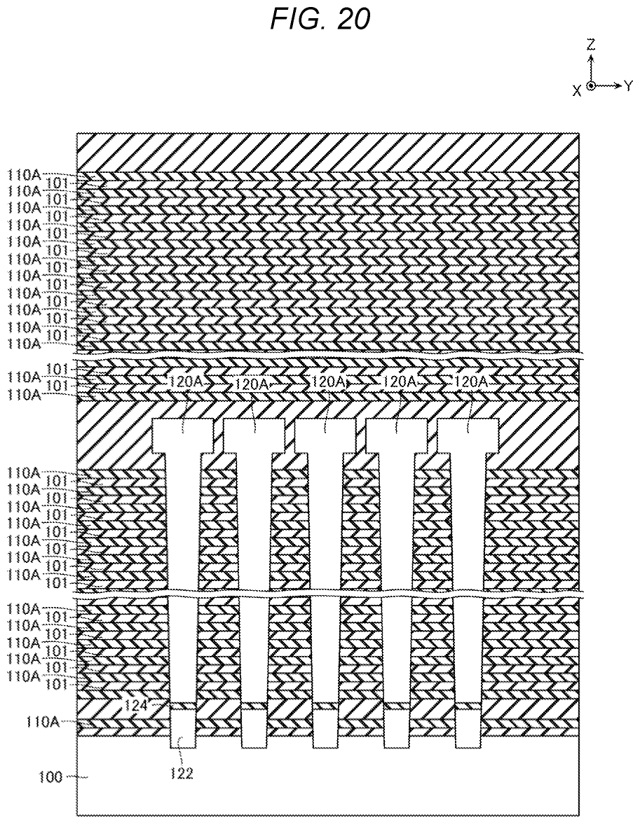

Next, for example, as shown in FIG. 20, a plurality of insulating layers 110A and 101 are formed above the structure as shown in FIG. 13. The process is performed by, for example, a method such as CVD. The plurality of insulating layers 110A and 101 are formed in the memory cell array region R_{MCA} and the hookup region R_{HU} described with reference to FIG. 2. In the process, the insulating layer 102 is formed in the row decoder region R_{RD} and the peripheral circuit region R_{P} (see FIG. 29).

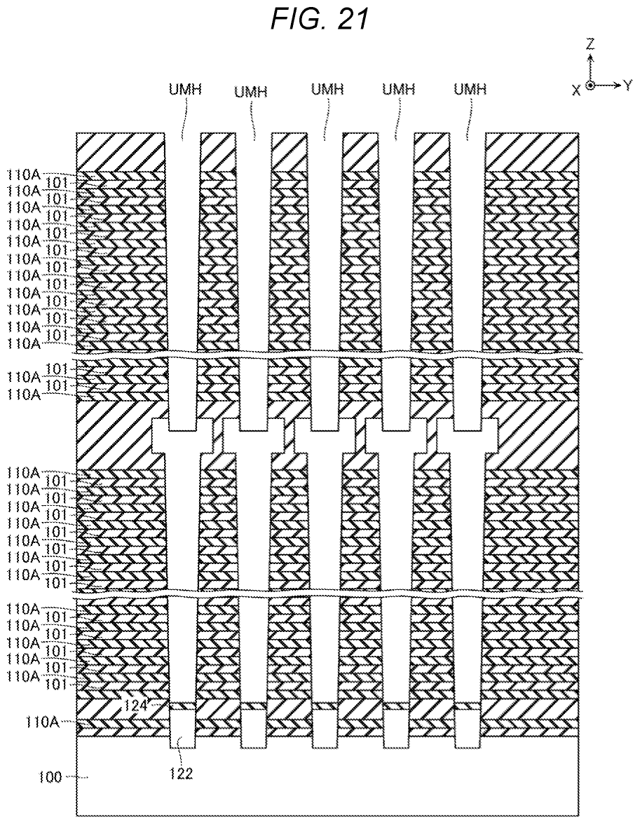

Next, for example, as shown in FIG. 21, a plurality of memory holes UMH are formed at positions corresponding to the semiconductor layers 120. Each memory hole UMH is a through via hole that extends along the Z direction, penetrates the insulating layers 101 and the insulating layers 110A, and exposes the upper surface of the amorphous silicon film 120A. The process is performed by, for example, a method such as RIE.

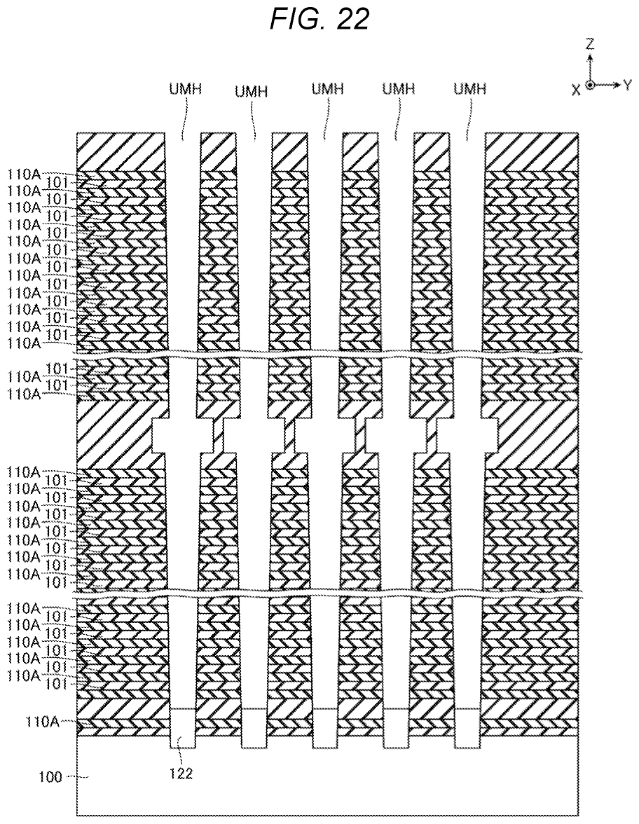

Next, for example, as shown in FIG. 22, the amorphous silicon film 120A and the insulating layer 124 are removed from each memory hole UMH. The process is performed by, for example, a method such as wet etching.

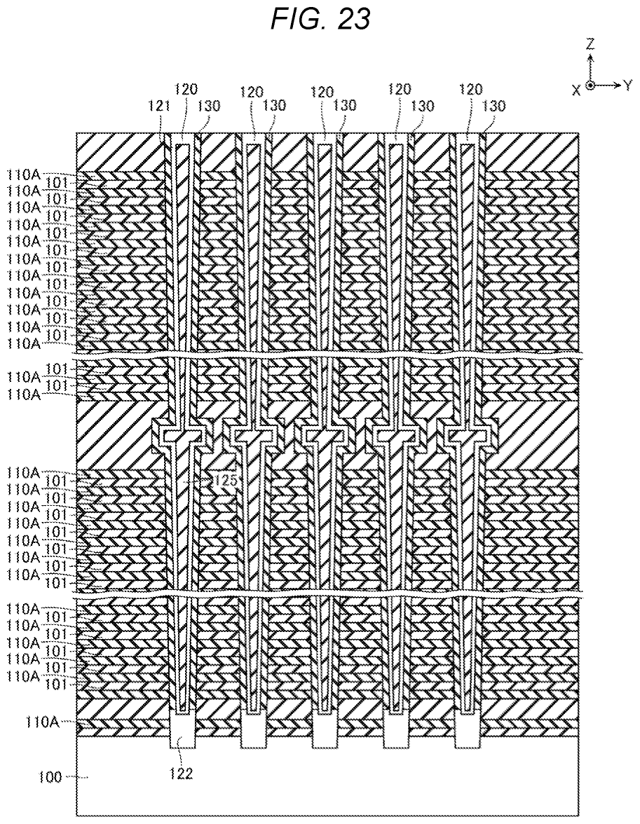

Next, as shown in FIG. 23, for example, the gate insulating film 130, the semiconductor layer 120, and the insulating layer 125 are formed inside each of the memory holes LMH and UMH. The process is performed by, for example, methods such as CVD and RIE.

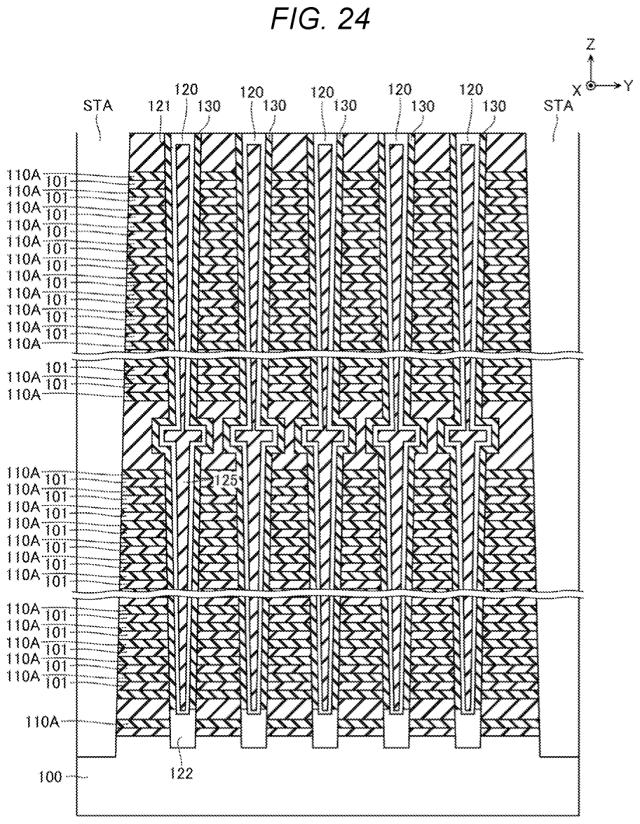

Next, as shown in FIG. 24, for example, a groove STA is formed at a position corresponding to the inter-block structure ST. The groove STA is a groove that extends along the Z direction and the X direction, divides the insulating layers 101 and the insulating layers 110A in the Y direction, and exposes the upper surface of the semiconductor substrate 100. The process is performed by, for example, a method such as RIE.

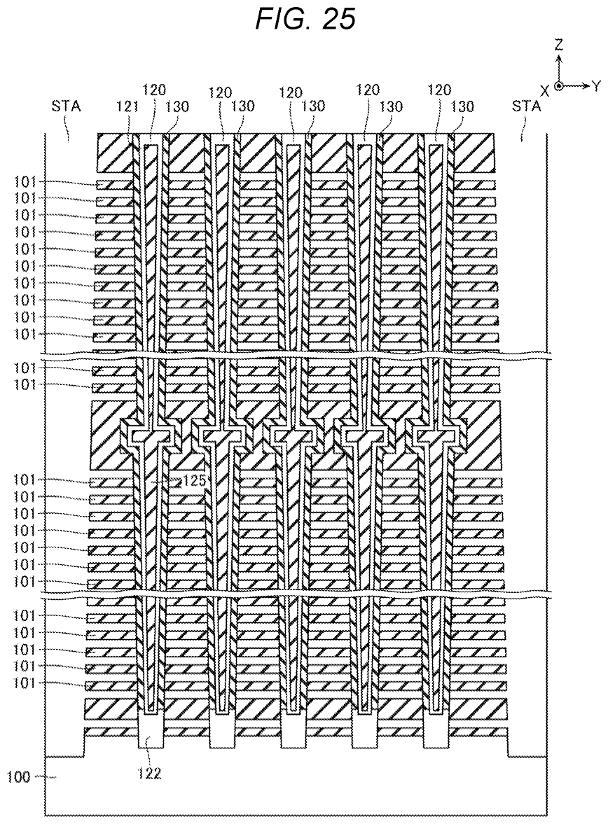

Next, for example, as shown in FIG. 25, the insulating layers 110A are removed through the groove STA. The process is performed by, for example, a method such as wet etching.

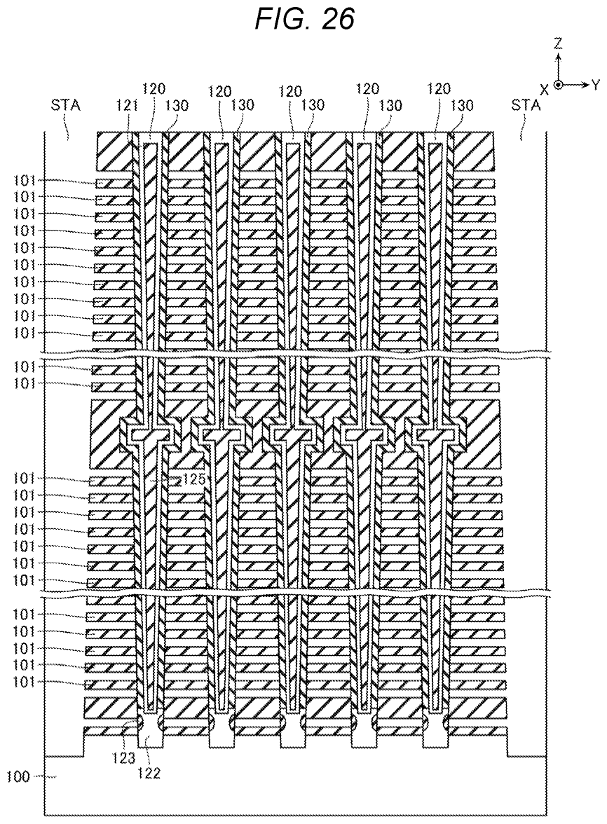

Next, for example, as shown in FIG. 26, the insulating layers 123 are formed. The process is performed by, for example, a method such as an oxidation treatment.

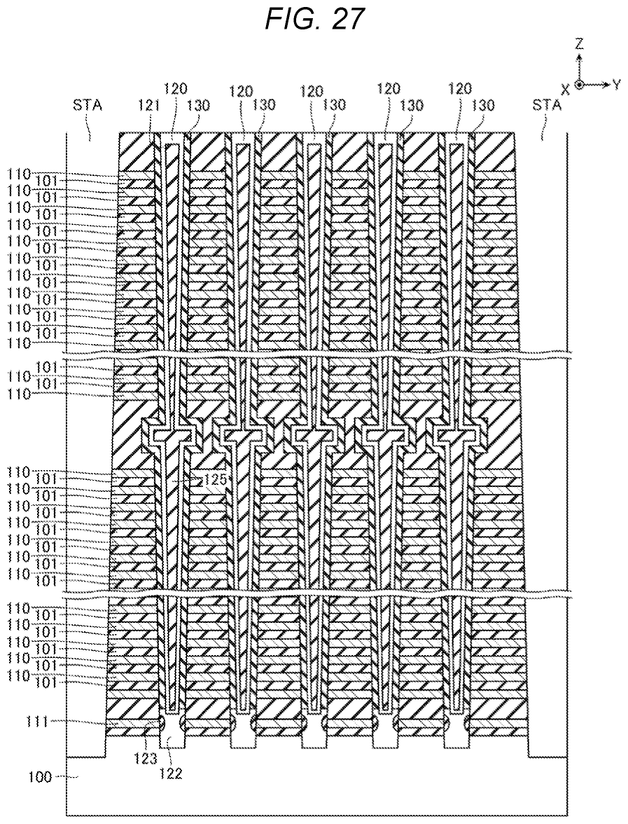

Next, for example, as shown in FIG. 27, the conductive layers 110 and the conductive layer 111 are formed. The process is performed by, for example, a method such as CVD.

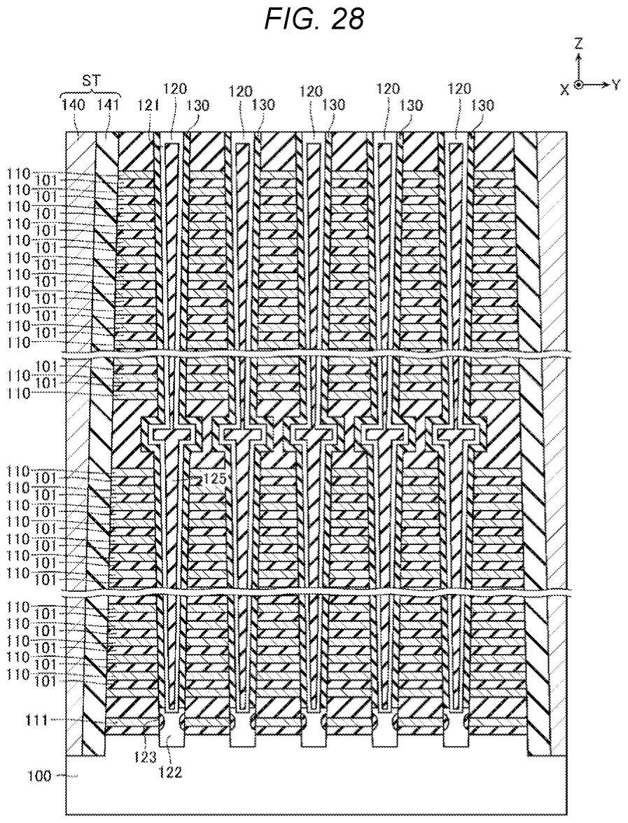

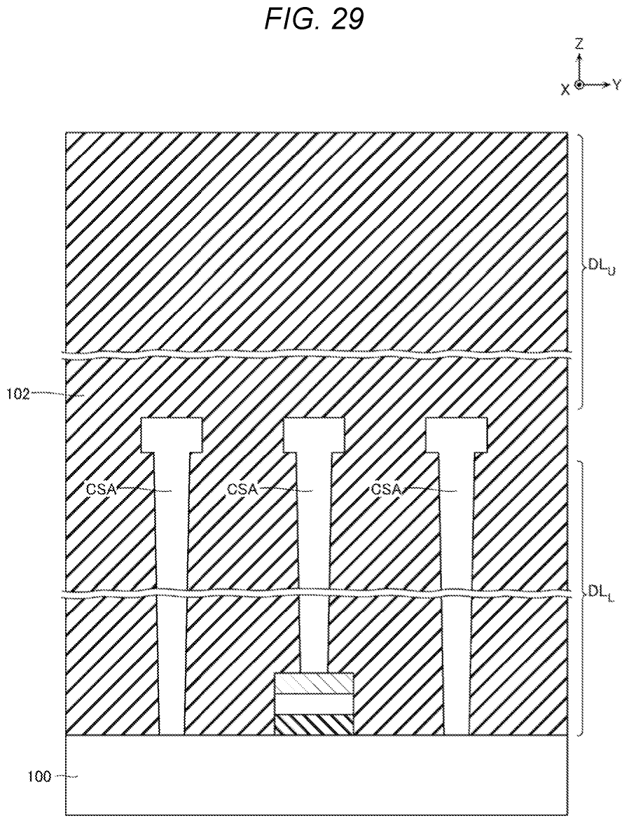

Next, as shown in FIG. 28, for example, the inter-block structure ST is formed in the groove STA. The process is performed by, for example, methods such as CVD and RIE.

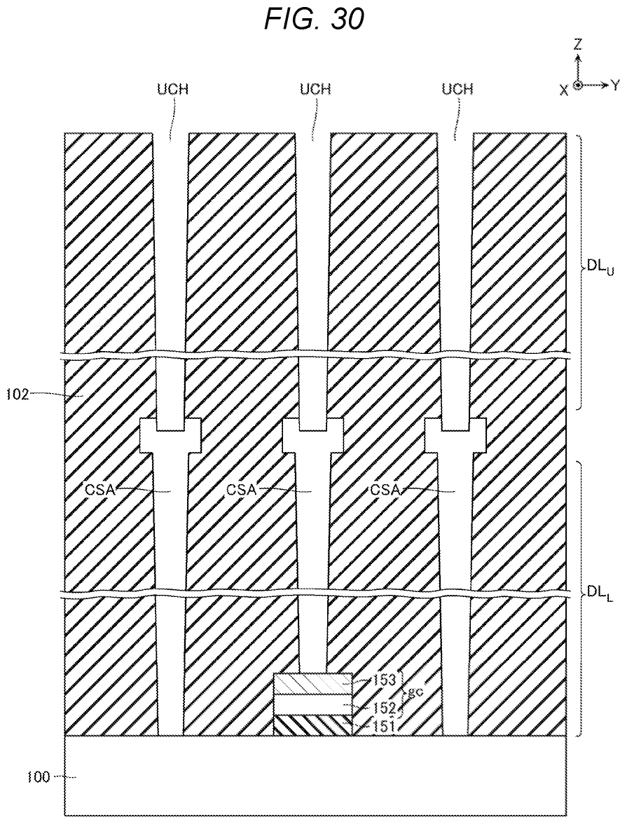

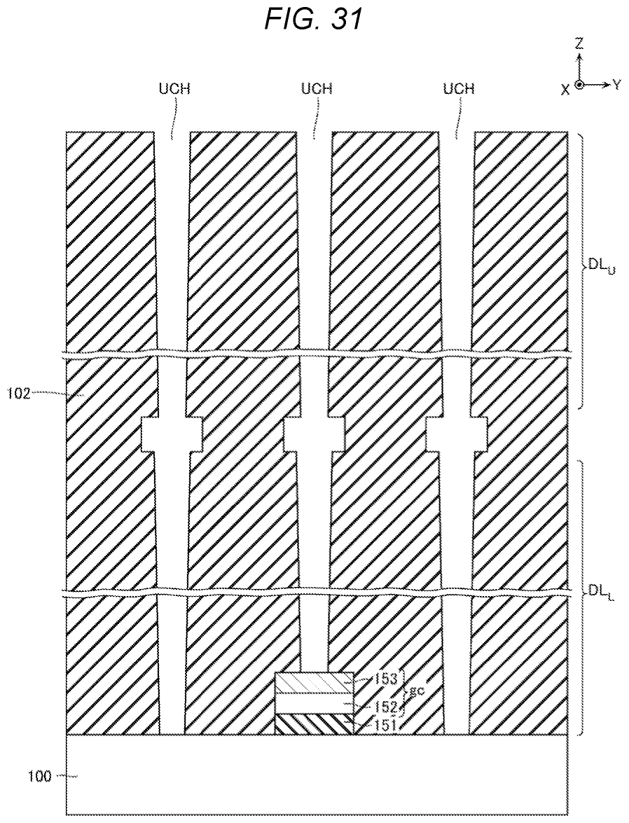

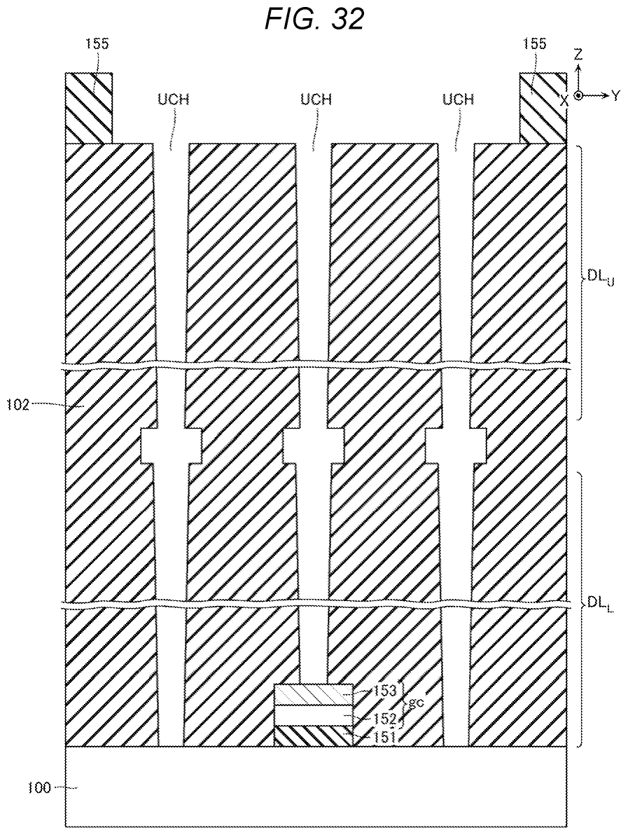

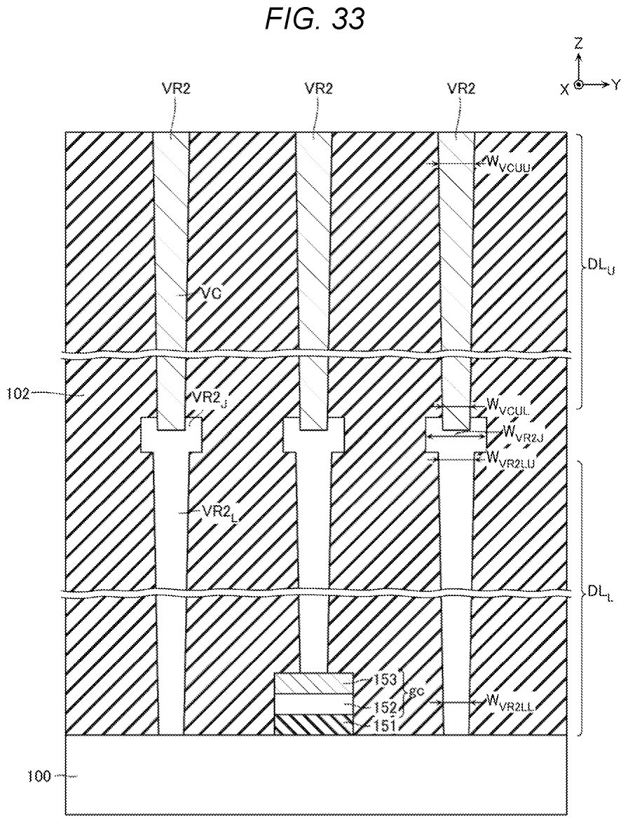

Next, as shown in FIGS. 29 and 30, for example, a plurality of contact holes UCH are formed at positions corresponding to the via contact electrodes CS and the via resistors VR. Each contact hole UCH is a through via hole that extends along the Z direction, penetrates the insulating layer 102, and exposes the upper surface of the amorphous silicon film CSA. The process is performed by, for example, a method such as RIE.

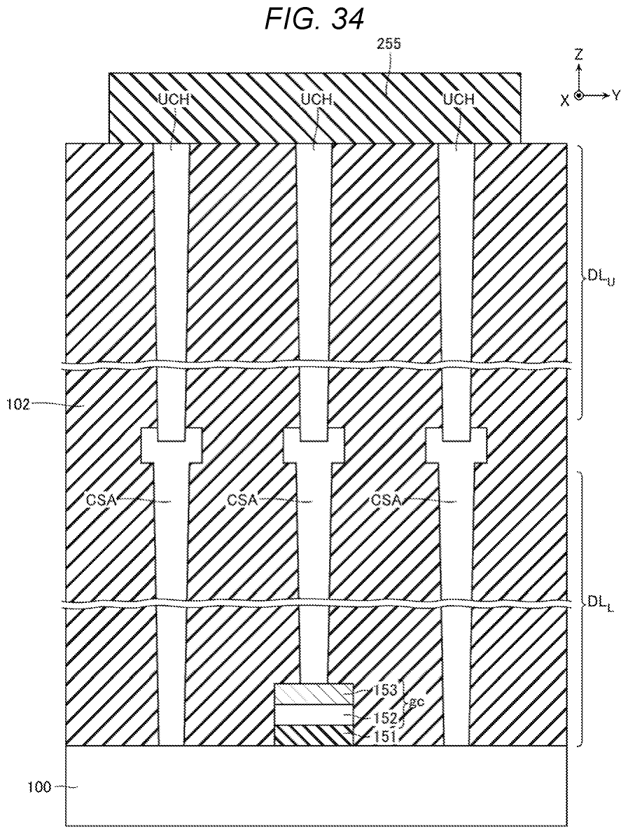

Next, for example, as shown in FIG. 31, the amorphous silicon film CSA is removed from each contact hole UCH. The process is performed by, for example, a method such as wet etching.

Next, for example, as shown in FIG. 32, among the contact holes LCH and UCH, those provided at positions other than the positions corresponding to the via resistors VR are covered by a resist 155.

Next, for example, as shown in FIG. 7, the via resistors VR are formed in some of the contact holes LCH and UCH. In the process, each via resistor VR is formed by, for example, a method such as CVD and CMP. For example, the resist 155 illustrated in FIG. 32 is removed.

Next, as shown in FIG. 6, for example, the via contact electrodes CS are formed in some of the contact holes LCH and UCH. The process is performed by, for example, a method such as CVD and chemical mechanical polishing (CMP).

After that, the memory die MD is formed by forming wiring and the like and dividing the wafer by dicing.

[Effect]

As described with reference to FIG. 4, the memory die MD includes the plurality of conductive layers 110 arranged along the Z direction, the plurality of semiconductor layers 120 extending along the Z direction, and the gate insulating films 130 provided therebetween. The memory die MD includes the via resistors VR.

Here, the thickness of the device layers DL_{L} and DL_{U} in the Z direction increases as the integration becomes higher. Each via resistor VR extends along the Z direction through the device layers DL_{L} and DL_{U} so as to have an enough length (resistor length) in the Z direction to provide the necessary resistance value. Therefore, the circuit area can be significantly reduced as compared with the case where, for example, a part of the wiring layer GC or the semiconductor substrate 100 is used as a resistance element.

For example, when a part of the wiring layer GC is used as a resistance element, the material of the wiring layer GC needs to be selected considering the characteristics of the transistor Tr and the like. The material of the via resistors VR may be selected relatively freely according to manufacturing conditions or the like. For example, when a semiconductor layer such as silicon (Si) containing N-type impurities or P-type impurities is used as the material for the via resistors VR, the characteristics of the via resistors VR can be adjusted in a relatively easy manner by adjusting the impurity concentration. Therefore, according to the via resistors VR according to the present embodiment, it is possible to implement resistance elements having suitable characteristics in a relatively easy manner.

### Second Embodiment

Next, a semiconductor storage device according to a second embodiment will be described with reference to FIG. 33. FIG. 33 is a schematic cross-sectional view of the semiconductor storage device according to the second embodiment.

The semiconductor storage device according to the second embodiment is basically configured in the same manner as the semiconductor storage device according to the first embodiment. However, the semiconductor storage device according to the second embodiment includes via resistors VR2 instead of the via resistors VR.

Each via resistor VR2 extends along the Z direction. The lower end of the via resistor VR2 is connected to the active region 100A of the semiconductor substrate 100 or the upper surface of the electrode gc. The upper end of the via resistor VR2 is connected to the wiring m0.

The via resistor VR2 includes a resistor region VR2L in the device layer DL_{L} and a conductor region VC in the device layer DL_{U}. The via resistor VR2 includes a resistor region VR2_{J} connected to the upper end of the resistor region VR2_{L} and the lower end of the conductor region VC. The resistor region VR2_{L} and the resistor region VR2_{J} may include, for example, a semiconductor layer made of, for example, silicon (Si) containing N-type impurities or P-type impurities. The conductor region VC may include, for example, a barrier conductive film made of, for example, titanium nitride (TiN) and a stacked metal film made of, for example, tungsten (W).

The resistor region VR2_{L} is a substantially columnar region extending along the Z direction. The outer peripheral surface of the resistor region VR2_{L} is surrounded by the insulating layer 102 in the device layer DL_{L}. The radial width W_{VR2LL} of the lower end portion of the resistor region VR2_{L} is smaller than the radial width W_{VR2LU} of the upper end portion of the resistor region VR2_{L} (for example, the portion located above the plurality of conductive layers 110 in the device layer DL_{L}). The lower end portion of the resistor region VR2_{L} connected to the semiconductor substrate 100 may be, for example, a portion located below the plurality of conductive layers 110 in the device layer DL_{L}. The lower end portion of the resistor region VR2_{L} connected to the electrode gc may be, for example, a connection portion with the electrode gc.

The conductor region VC is a substantially columnar region extending in the Z direction. The outer peripheral surface of the conductor region VC is surrounded by the insulating layer 102 in the device layer DL_{U}. The radial width W_{VCUL} of the lower end portion of the conductor region VC (for example, the portion located below the plurality of conductive layers 110 in the device layer DL_{U}) is smaller than the radial width W_{VCUU} of the upper end portion of the conductor region VC (for example, the portion located above the plurality of conductive layers 110 in the device layer DL_{U}) and the above-described width W_{VR2LU}.

Each resistor region VR2_{J} is provided above the plurality of conductive layers 110 in the device layer DL_{L} in the z direction and is provided below the plurality of conductive layers 110 in the device layer DL_{U} in the z direction. The radial width W_{VR2J} of the resistor region VR2_{J} is larger than the widths W_{VRLU} and W_{VCUU}.

Next, a method of manufacturing the semiconductor storage device according to the second embodiment will be described with reference to FIG. 34. FIG. 34 is a schematic cross-sectional view for illustrating the manufacturing method. FIG. 34 shows a cross section corresponding to FIG. 33.

In manufacturing the semiconductor storage device according to the present embodiment, first, among the processes in the method of manufacturing the semiconductor storage device according to the first embodiment, the processes up to the process described with reference to FIG. 30 are performed.

Next, for example, as shown in FIG. 34, among the contact holes LCH and UCH, those provided at the positions corresponding to the via resistors VR2 are covered by a resist 255.

Next, for example, as shown in FIG. 31, the amorphous silicon film CSA is removed from each contact hole LCH and UCH corresponding to the via contact electrode CS. The process is performed by, for example, a method such as wet etching.

Next, for example, as shown in FIG. 30, the resist 255 described with reference to FIG. 34 is removed.

Next, as shown in FIGS. 6 and 33, for example, the via contact electrodes CS and the via resistors VR2 are formed. The process is performed by, for example, a method such as CVD and CMP.

After that, the semiconductor storage device according to the second embodiment is formed by forming wiring and the like and dividing the wafer by dicing.

According to the semiconductor storage device according to the second embodiment, it is possible to reduce the circuit area and implement resistance elements having suitable characteristics, similarly to the semiconductor storage device according to the first embodiment.

In the method for manufacturing a semiconductor storage device according to the second embodiment, the amorphous silicon film CSA used as a sacrificial film is used as the resistor region VR2_{L} and the resistor region VR2_{J} of each via resistor VR2, and the conductor region VC of the via resistor VR2 is formed at the same time as the via contact electrode CS. Therefore, the number of manufacturing processes can be reduced as compared with the manufacturing method of the semiconductor storage device according to the first embodiment.

### Third Embodiment

Next, a semiconductor storage device according to a third embodiment will be described.

The semiconductor storage device according to the third embodiment is basically configured in the same manner as the semiconductor storage device according to the first embodiment. However, the semiconductor storage device according to the third embodiment includes the via resistors VR2 (see FIG. 33) according to the second embodiment in addition to the via resistors VR (see FIG. 7) according to the first embodiment.

Next, a method of manufacturing the semiconductor storage device according to the third embodiment will be described.

In manufacturing the semiconductor storage device according to the present embodiment, first, among the processes in the method for manufacturing the semiconductor storage device according to the second embodiment, the processes up to the process described with reference to FIG. 34 are performed.

Next, for example, as shown in FIG. 31, the amorphous silicon film CSA is removed from each contact hole LCH and UCH corresponding to the via contact electrode CS and the via resistor VR. The process is performed by, for example, a method such as wet etching.

Next, for example, as shown in FIG. 32, among the contact holes LCH and UCH, those provided at positions other than the positions corresponding to the via resistors VR are covered by the resist 155.

Next, for example, as shown in FIG. 7, the via resistors VR are formed in the contact holes LCH and UCH. The process is performed by, for example, a method such as CVD and CMP.

Next, for example, as shown in FIG. 30, the resist 155 described with reference to FIG. 32 and the resist 255 described with reference to FIG. 34 are removed.

Next, as shown in FIGS. 6 and 33, for example, the via contact electrodes CS and the via resistors VR2 are formed. The process is performed by, for example, a method such as CVD and CMP.

After that, the semiconductor storage device according to the third embodiment is formed by forming wiring and the like and dividing the wafer by dicing.

According to the semiconductor storage device according to the third embodiment, it is possible to reduce the circuit area and implement resistance elements having suitable characteristics, similarly to the semiconductor storage device according to the first embodiment.

According to the semiconductor storage device according to the third embodiment, it is possible to simultaneously form the via resistors VR and VR2 having two resistance values. Thereby, the circuit area can be further reduced.

### Fourth Embodiment

[Structure of Memory Die MD4]

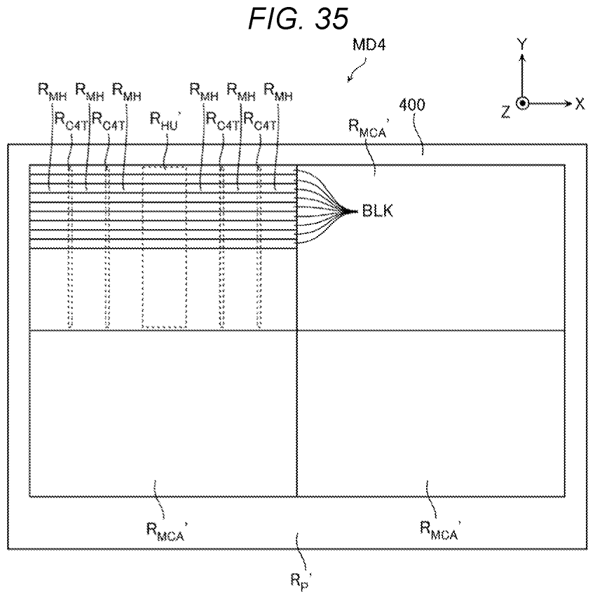

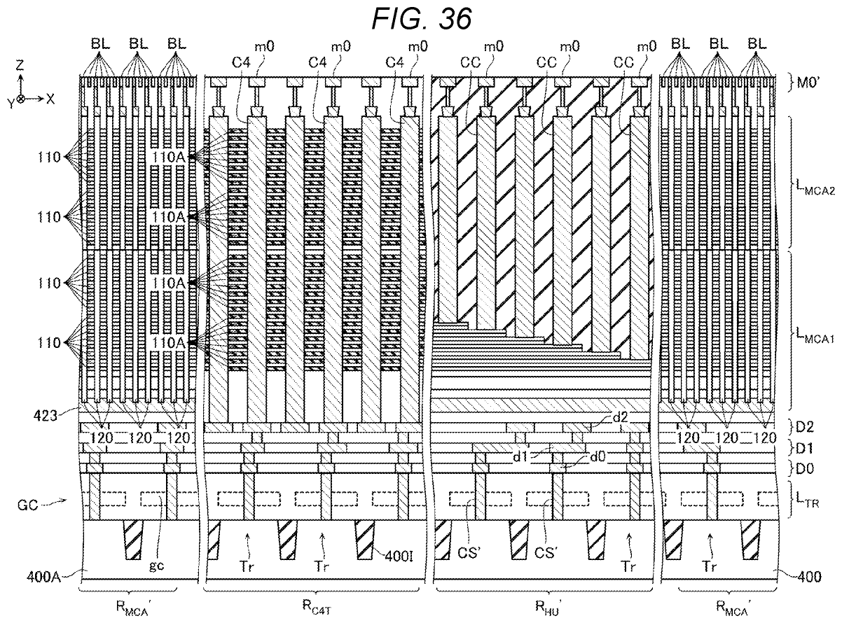

Next, a semiconductor storage device according to a fourth embodiment will be described with reference to FIGS. 35 to 38. FIG. 35 is a schematic plan view of a memory die MD4 according to the fourth embodiment. FIGS. 36 to 38 are schematic cross-sectional views of the memory die MD4.

The memory die MD4 includes a semiconductor substrate 400, for example, as shown in FIG. 35. In the illustrated example, the semiconductor substrate 400 includes four memory cell array regions R_{MCA}′ arranged along the X and Y directions. The memory cell array region R_{MCA}′ includes a plurality of memory hole regions RmH arranged along the X direction and a plurality of contact connection regions R_{C4T} between the memory hole regions R_{MH}. A hookup region R_{HU}′ is provided at the center position of the memory cell array region R_{MCA}′ in the X direction. A peripheral circuit region R_{P}′ is provided at the end portion of the semiconductor substrate 400 in the Y direction. The peripheral circuit region R_{P}′ extends in the X direction along the end portion of the semiconductor substrate 400 in the Y direction.

As shown in FIG. 36, for example, the memory die MD4 includes the semiconductor substrate 400, a transistor layer L_{TR} on the semiconductor substrate 400, a wiring layer D0 above the transistor layer L_{TR}, a wiring layer D1 above the wiring layer D0, a wiring layer D2 above the wiring layer D1, a memory cell array layer L_{MCA1} above the wiring layer D2, a memory cell array layer L_{MCA2} above the memory cell array layer L_{MCA1}, and a wiring layer M0′ above the memory cell array layer L_{MCA2}.

[Structure of Semiconductor Substrate 400]

The semiconductor substrate 400 is configured in almost the same manner as the semiconductor substrate 100 (see FIG. 3). An active region 400A and insulating regions 4001 are provided on the surface of the semiconductor substrate 400.

[Structure of Transistor Layer L_{TR}]

The transistor layer L_{TR} is configured in almost the same manner as the row decoder region R_{RD} and the peripheral circuit region R_{P} of the device layer DL_{L} of the memory die MD (see FIG. 3). However, the transistor layer L_{TR} includes via contact electrodes CS′ instead of the via contact electrodes CS.

Each via contact electrode CS′ extends along the Z direction and is connected to the upper surface of the semiconductor substrate 400 or the electrode gc at the lower end thereof. An impurity region containing N-type impurities or P-type impurities is provided at the connection portion between the via contact electrode CS′ and the semiconductor substrate 400. The via contact electrode CS′ may include, for example, a barrier conductive film made of, for example, titanium nitride (TiN) and a stacked metal film made of, for example, tungsten (W).

[Structure of Wiring Layers D0, D1, and D2]

For example, as shown in FIG. 36, the plurality of wirings in the wiring layers D0, D1, and D2 are electrically connected to at least one of the elements in the memory cell array MCA and the elements in the peripheral circuit PC.

The wiring layers D0, D1, and D2 include a plurality of wirings d0, d1, and d2, respectively. Each of the plurality of wirings d0, d1, and d2 may include, for example, a barrier conductive film made of, for example, titanium nitride (TiN) and a stacked metal film made of, for example, tungsten (W).

[Structure of Memory Cell Array Layers L_{MCA1} and L_{MCA2} in Memory Hole Region R_{MH}]

The structure of the memory cell array layers L_{MCA1} and L_{MCA2} in the memory hole region R_{MH} is almost the same as the structure of the device layers DL_{L} and DL_{U} of the memory die MD (see FIG. 3) in the memory cell array region R_{MCA}.

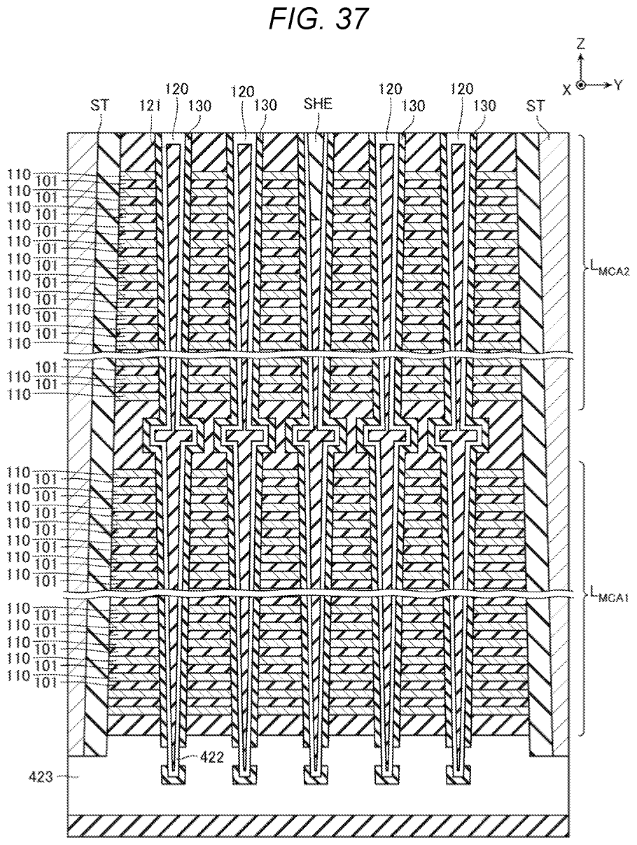

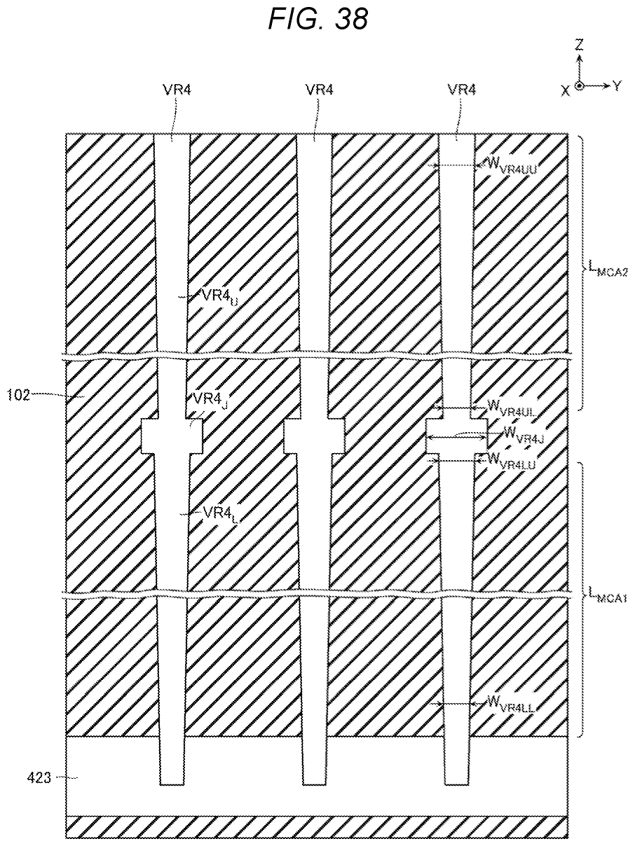

However, as shown in FIG. 37, for example, the semiconductor layers 122 are not provided at the lower ends of the plurality of semiconductor layers 120 in the memory hole regions R_{MH} of the memory cell array layers L_{MCA1} and L_{MCA2}. An impurity region 422 is provided at the lower end of the semiconductor layer 120 provided in each of the memory hole regions R_{MH} of the memory cell array layers L_{MCA1} and L_{MCA2}. The impurity region 422 contains, for example, N-type impurities such as phosphorus (P) or P-type impurities such as boron (B).

For example, as shown in FIG. 37, the memory hole region R_{MH} of the memory cell array layer L_{MCA1} includes a semiconductor layer 423 containing N-type impurities such as phosphorus (P) or P-type impurities such as boron (B). The lower end of each semiconductor layer 120 is connected to the semiconductor layer 423 instead of the semiconductor substrate 400.

[Structure of Memory Cell Array Layers L_{MCA1} and L_{MCA2} in Contact Connection Region R_{C4T}]

The contact connection regions RC4T of the memory cell array layers L_{MCA1} and L_{MCA2} include, for example, a plurality of insulating layers 110A arranged along the Z direction and a plurality of via contact electrodes C4 extending along the Z direction, as shown in FIG. 36. Insulating layers 101 such as silicon oxide (SiO₂) are provided between the plurality of insulating layers 110A arranged along the Z direction.

A plurality of via contact electrodes C4 are arranged along the X direction. Each via contact electrode C4 may include a barrier conductive film made of, for example, titanium nitride (TiN) and a stacked metal film made of, for example, tungsten (W). The outer peripheral surface of the via contact electrode C4 is surrounded by the insulating layers 110A and the insulating layers 101 and is connected to the insulating layers 110A and the insulating layers 101. As shown in FIG. 36, for example, each via contact electrode C4 extends along the Z direction and is connected to the corresponding wiring m0 in the wiring layer M0 at the upper end thereof and to the corresponding wiring d2 in the wiring layer D2 at the lower end thereof.

[Structure in Hookup Region R_{HU}′ of Memory Cell Array Layers L_{MCA1} and L_{MCA2}]

The structure in the hookup Region R_{HU}′ of the memory cell array layers L_{MCA1} and L_{MCA2} is almost the same as the structure of the hookup area R_{HU}′ of the device layers DL_{L} and DL_{U} of the memory die MD (FIG. 3).

[Via Resistors VR4]A plurality of via resistors VR4 are provided in any region of the memory die MD4. Each via resistor VR4 extends along the Z direction, for example, as shown in FIG. 38. The lower end of the via resistor VR4 is connected to the semiconductor layer 423. The upper end of the via resistor VR4 is connected to the wiring m0. The via resistor VR4 may include, for example, a semiconductor layer made of, for example, silicon (Si) containing N-type impurities or P-type impurities.

The via resistor VR4 includes a resistor region VR4L in the memory cell array layer L_{MCA1} and a resistor region VR4_{U} in the memory cell array layer L_{MCA2}. The via resistor VR4 includes a resistor region VR4_{J} connected to the upper end of the resistor region VR4_{L} and the lower end of the resistor region VR4_{U}.

The resistor region VR4_{L} is a substantially columnar region extending along the Z direction. The outer peripheral surface of the resistor region VR4_{L} is surrounded by the insulating layer 102 in the memory cell array layer L_{MCA1}. The radial width W_{VR4LL} of the lower end portion of the resistor region VR4_{L} (for example, the portion located below the plurality of conductive layers 110 in the memory cell array layer L_{MCA1}) is smaller than the radial width W_{VR4LU} of the upper end portion of the resistor region VR4_{L} (for example, the portion located above the plurality of conductive layers 110 in the memory cell array layer L_{MCA1}).

The resistor region VR4_{U} is a substantially columnar region extending along the Z direction. The outer peripheral surface of the resistor region VR4_{U} is surrounded by the insulating layer 102 in the memory cell array layer L_{MCA2}. The radial width W_{VR4UL} of the lower end portion of the resistor region VR4_{U} (for example, the portion located below the plurality of conductive layers 110 in the memory cell array layer L_{MCA2}) is smaller than the radial width W_{VR4UU} of the upper end portion of the resistor region VR4_{U} (for example, the portion located above the plurality of conductive layers 110 in the memory cell array layer L_{MCA2}) and the above-described width W_{VR4LU}.

Each resistor region VR4_{J} is provided above the plurality of conductive layers 110 in the memory cell array layer L_{MCA1} in the Z direction and below the plurality of conductive layers 110 in the memory cell array layer L_{MCA2} in the Z direction. The radial width W_{VR4J} of the resistor region VR4_{J} is larger than the widths W_{VR4LU} and W_{VR4UU}.

[Manufacturing Method]

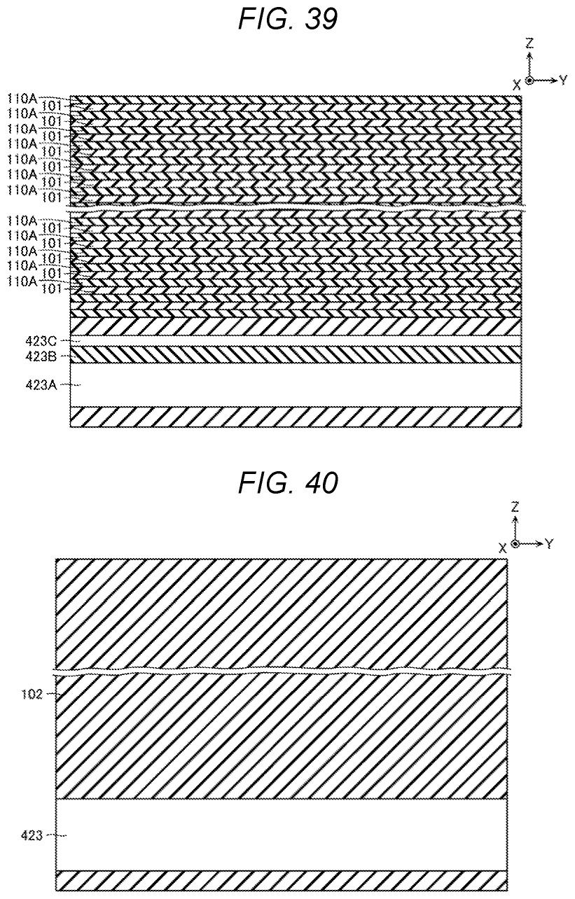

Next, a method of manufacturing the semiconductor storage device according to the fourth embodiment will be described with reference to FIGS. 39 to 49. FIGS. 39 to 49 are schematic cross-sectional views for illustrating the manufacturing method. FIGS. 39, 41, 43, 45, 48, and 49 show cross sections corresponding to FIG. 37. FIGS. 40, 42, 44, 46, and 47 show cross sections corresponding to FIG. 38.

In manufacturing the semiconductor storage device according to the present embodiment, first, the transistor layer L_{TR} and the wiring layers D0 to D2 described with reference to FIG. 36 are formed on the semiconductor substrate 400.

Next, for example, as shown in FIG. 39, a semiconductor layer 423A, a sacrificial layer 423B, and a semiconductor layer 423C are formed above the semiconductor substrate 400. A plurality of insulating layers 110A and 101 are formed above the layers 423A, 423B, and 423C. The process is performed by, for example, a method such as CVD. The plurality of insulating layers 110A and 101 are formed in the memory cell array region R_{MCA}′ described with reference to FIGS. 35 and 36. As shown in FIG. 40, for example, here, the insulating layer 102 is formed in the peripheral circuit region R_{P}′.

Next, among the processes in the method for manufacturing the semiconductor storage device according to the first embodiment, the process described with reference to FIG. 9 is performed to form an amorphous silicon film 120A inside each memory hole LMH. The processes described with reference to FIGS. 11 to 13 are performed. In the processes, the same processing is performed on the peripheral circuit region R_{P}′.

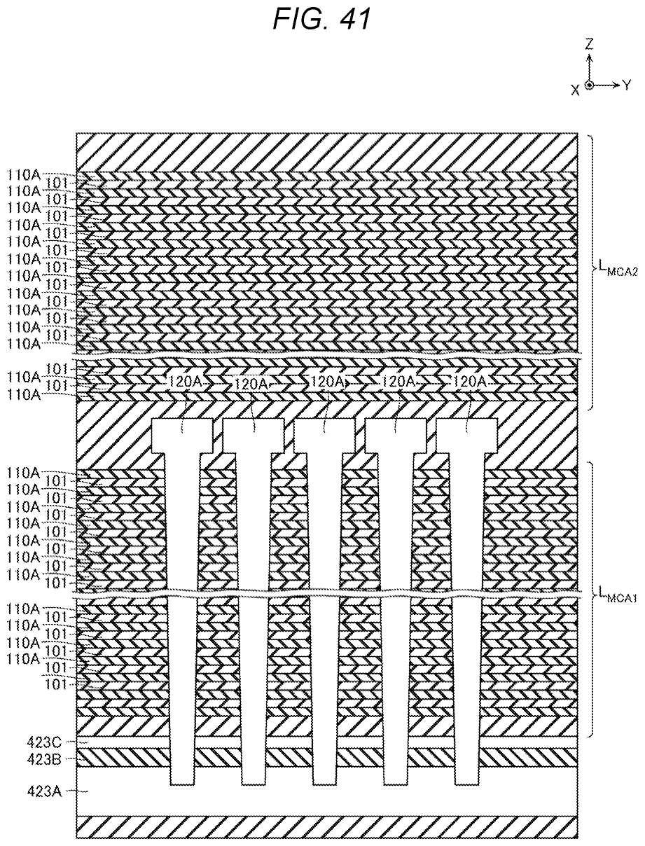

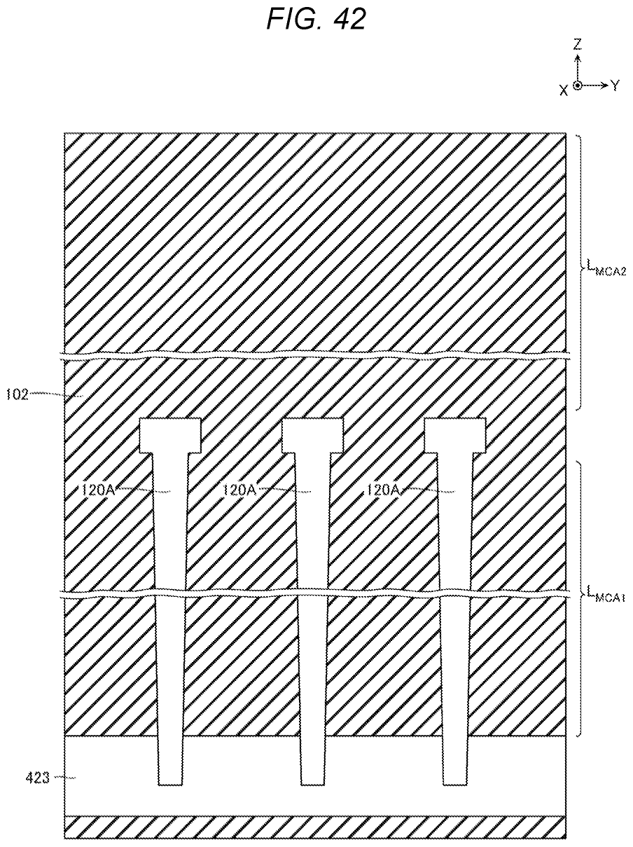

Next, for example, as shown in FIG. 41, the plurality of insulating layers 110A and 101 are formed above the structure formed by the above processes. The process is performed by, for example, a method such as CVD. The plurality of insulating layers 110A and 101 are formed in the memory cell array region R_{MCA}′ described with reference to FIGS. 35 and 36. As shown in FIG. 42, for example, in the process, the insulating layer 102 is formed in the peripheral circuit region R_{P}′.

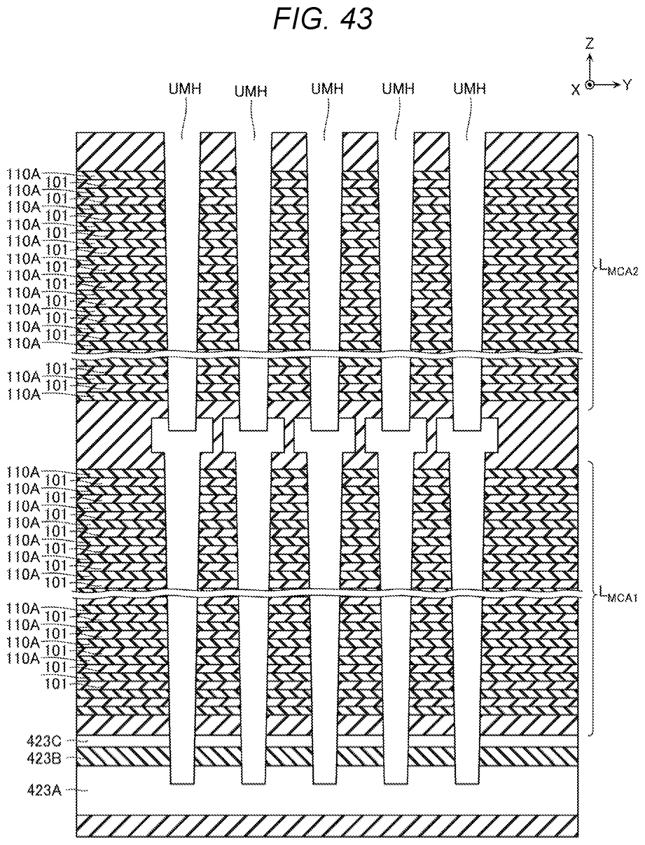

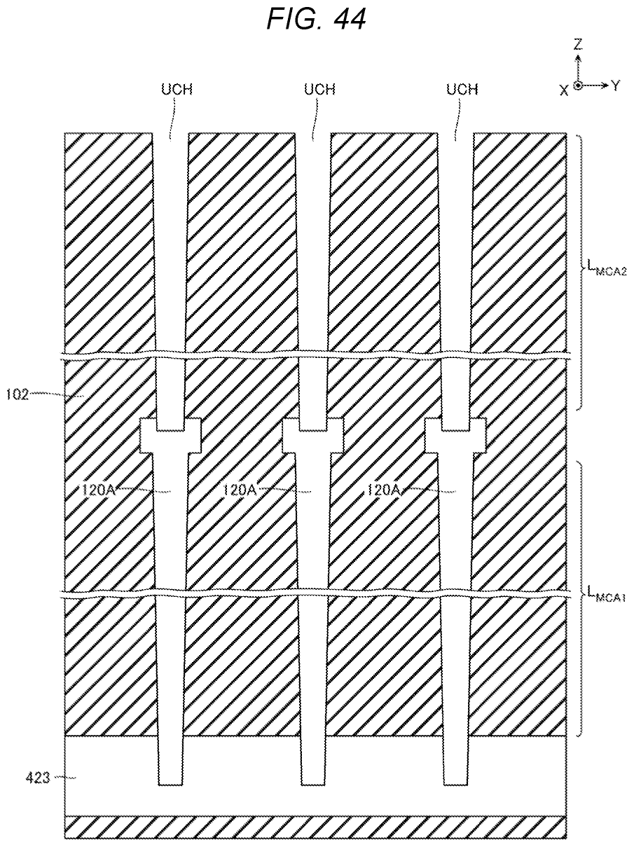

Next, for example, as shown in FIG. 43, a plurality of memory holes UMH are formed at positions corresponding to the semiconductor layers 120. For example, as shown in FIG. 44, a plurality of contact holes UCH are formed at positions corresponding to the via resistors VR4. The process is performed by, for example, a method such as RIE.

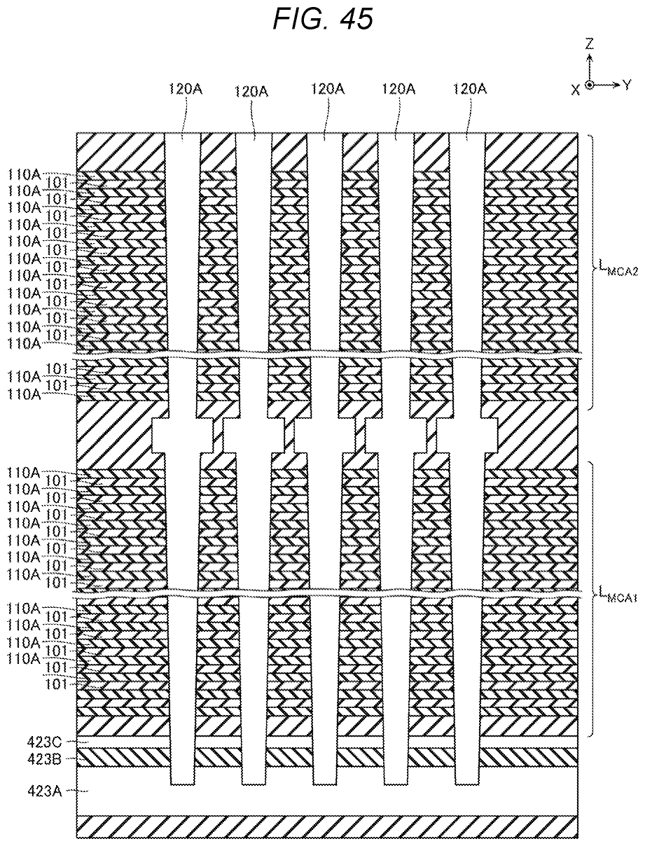

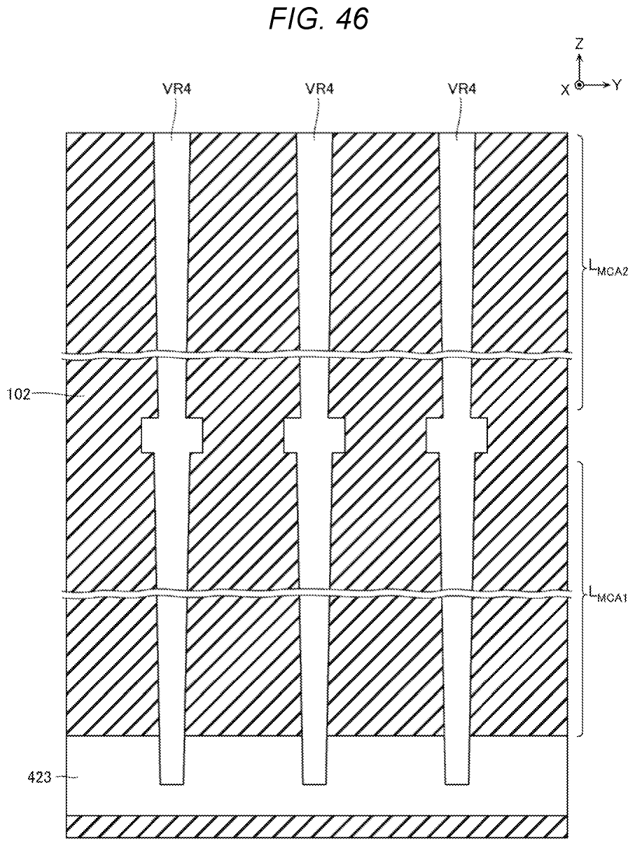

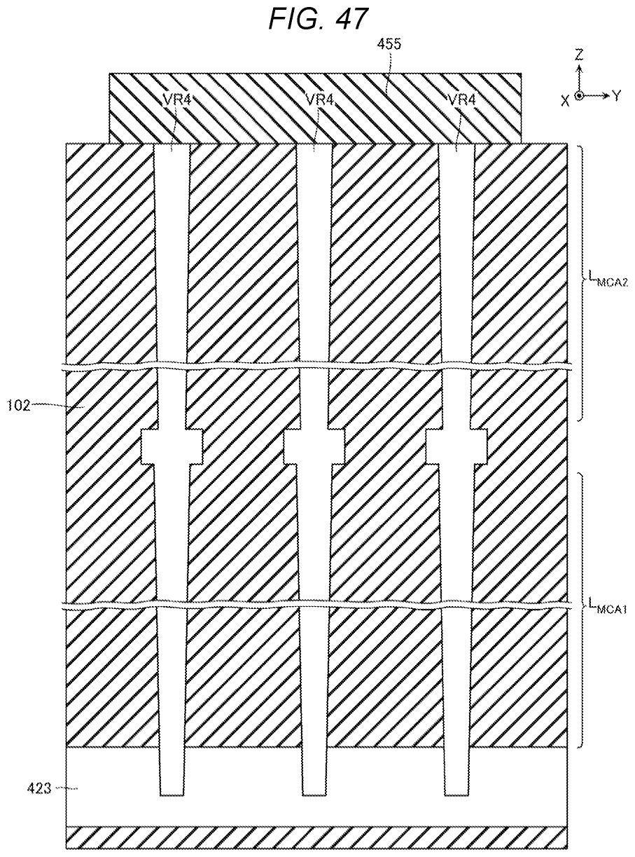

Next, for example, as shown in FIG. 45, an amorphous silicon film 120A is formed inside each memory hole UMH. For example, as shown in FIG. 46, the via resistor VR4 is formed inside each of the contact holes LCH and UCH. The process is performed by, for example, a method such as CVD.

Next, for example, as shown in FIG. 47, the upper surface of the via resistor VR4 is covered with a resist 455.

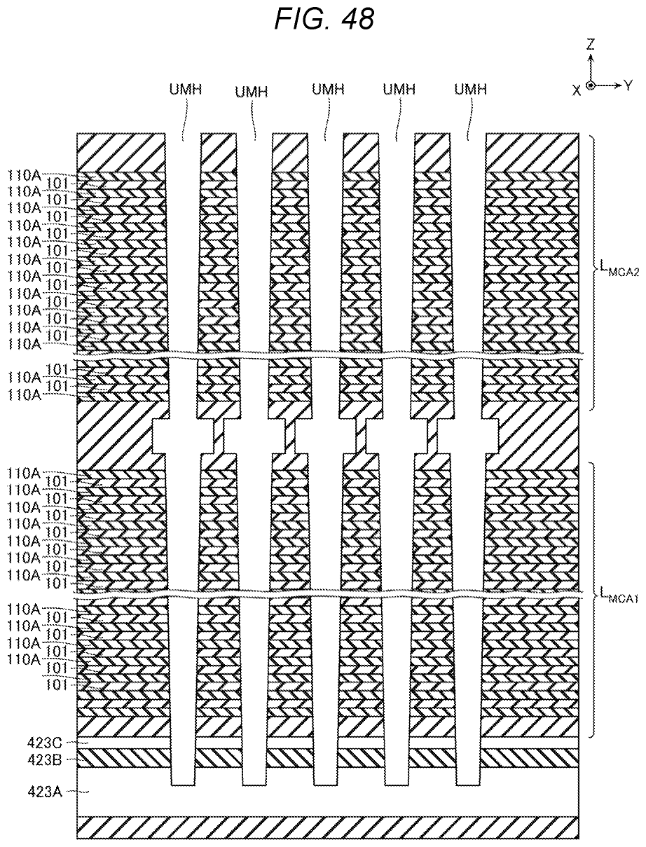

Next, for example, as shown in FIG. 48, the amorphous silicon film 120A is removed from the inside of each of the memory holes LMH and UMH. The process is performed by, for example, a method such as wet etching.

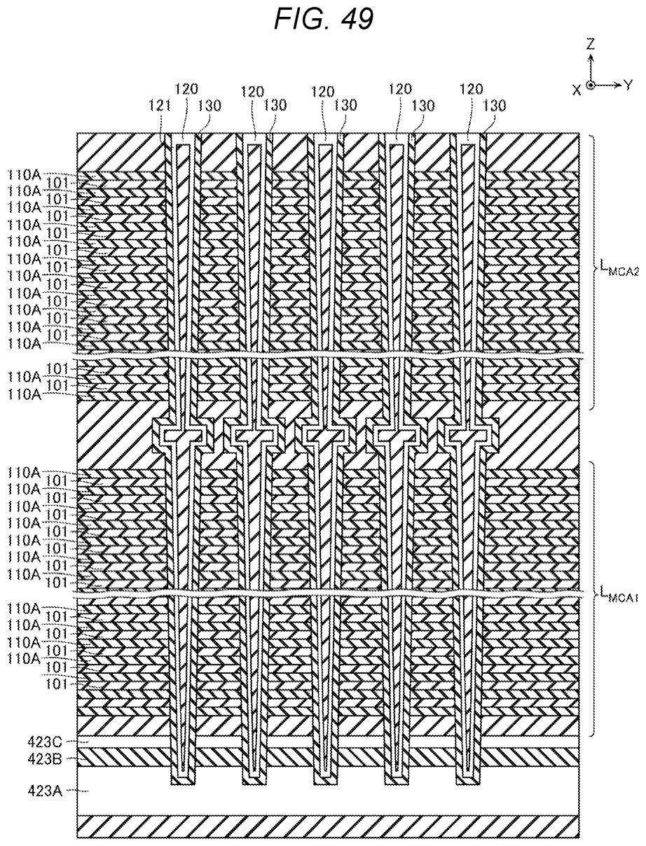

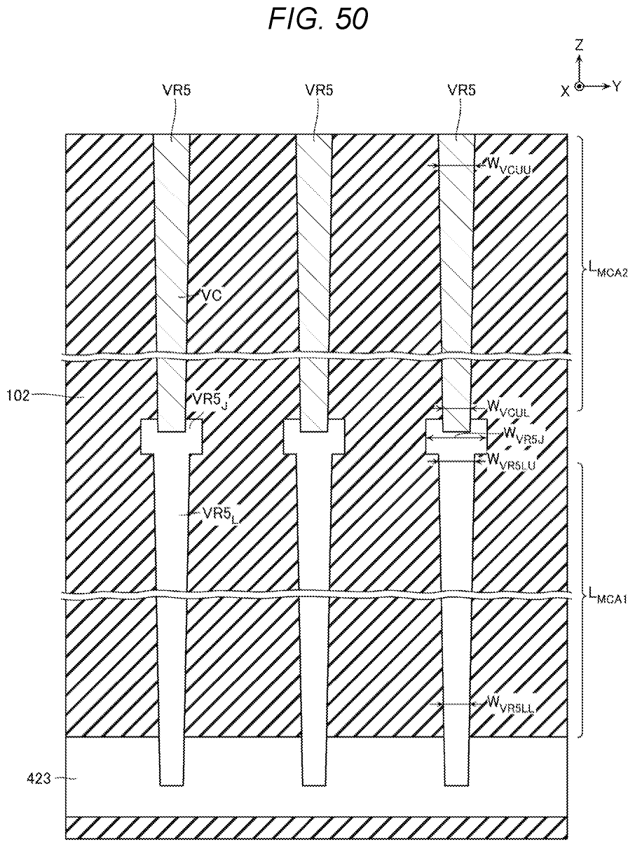

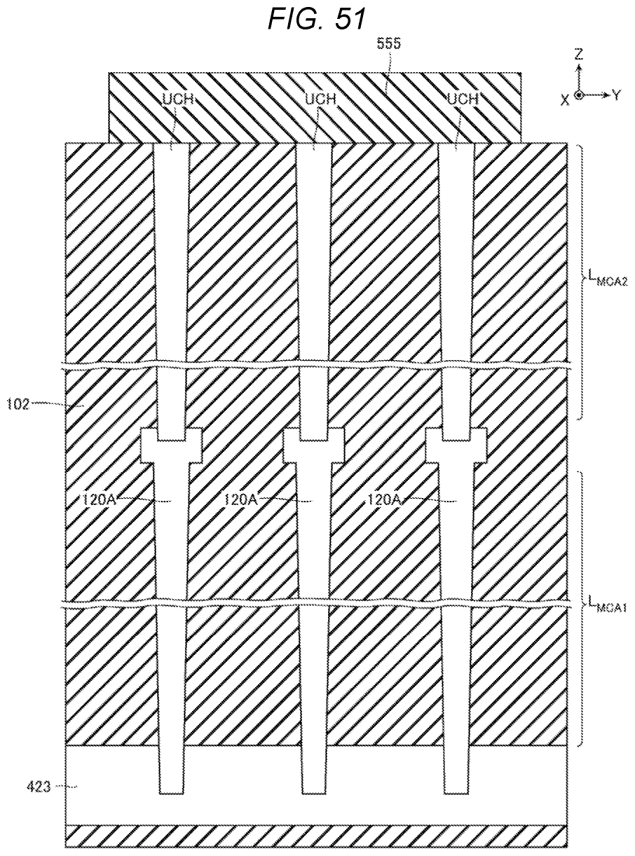

Next, as shown in FIG. 49, for example, the gate insulating film 130, the semiconductor layer 120, and the insulating layer 125 are formed inside each of the memory holes LMH and UMH. The process is performed by, for example, methods such as CVD and RIE.

After that, for example, among the processes in the method for manufacturing the semiconductor storage device according to the first embodiment, the processes described with reference to FIGS. 24 to 28 are performed to form wirings and the like, and the wafer is divided by dicing, thereby forming the memory die MD4.

[Effect]

According to the semiconductor storage device according to the fourth embodiment, it is possible to reduce the circuit area and implement resistance elements having suitable characteristics, similarly to the semiconductor storage device according to the first embodiment.

### Fifth Embodiment

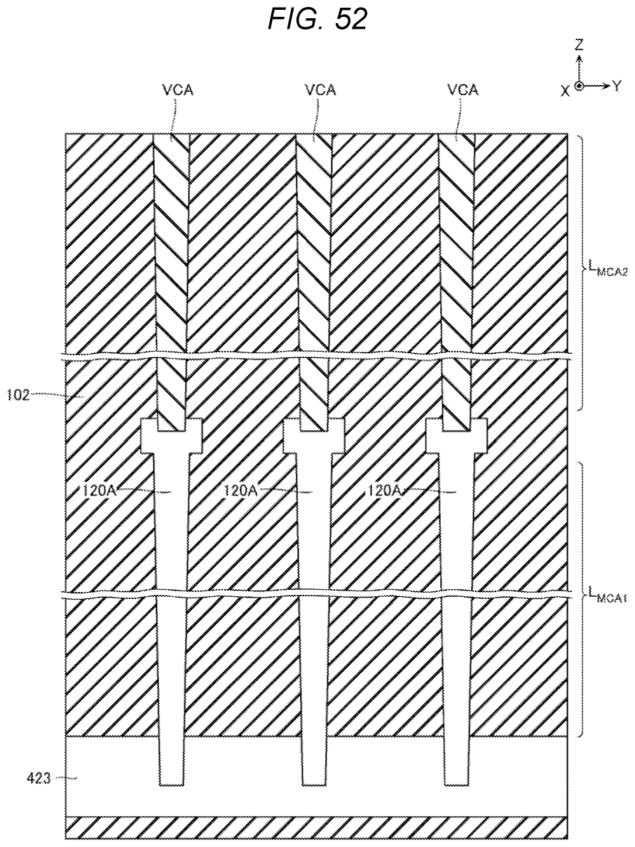

Next, a semiconductor storage device according to a fifth embodiment will be described with reference to FIG. 50. FIG. 50 is a schematic cross-sectional view of the semiconductor storage device according to the fifth embodiment.

The semiconductor storage device according to the fifth embodiment is basically configured in the same manner as the semiconductor storage device according to the fourth embodiment. However, the semiconductor storage device according to the fifth embodiment includes via resistors VR5 instead of the via resistors VR4.

Each via resistor VR5 extends along the Z direction. The lower end of the via resistor VR5 is connected to the semiconductor layer 423. The upper end of the via resistor VR5 is connected to the wiring m0.

The via resistor VR5 includes a resistor region VR5_{L} in the memory cell array layer L_{MCA1} and the conductor region VC in the memory cell array layer L_{MCA2}. The via resistor VR5 includes a resistor region VR5_{J} connected to the upper end of the resistor region VR5_{L} and the lower end of the conductor region VC. The resistor region VR5_{L} and the resistor region VR5_{J} may include, for example, a semiconductor layer made of, for example, silicon (Si) containing N-type impurities or P-type impurities.

The resistor region VR5_{L} is a substantially columnar region extending along the Z direction. The outer peripheral surface of the resistor region VR5_{L} is surrounded by the insulating layer 102 in the memory cell array layer L_{MCA1}. The radial width WVR5LL of the lower end portion of the resistor region VR5_{L} (for example, the portion located below the plurality of conductive layers 110 in the memory cell array layer L_{MCA1}) is smaller than the radial width W_{VR5LU} of the upper end portion of the resistor region VR5_{L} (for example, the portion located above the plurality of conductive layers 110 in the memory cell array layer L_{MCA1}) .

Each of the resistor regions VR5_{J} is provided above the plurality of conductive layers 110 in the memory cell array layer L_{MCA1} in the Z direction and below the plurality of conductive layers 110 in the memory cell array layer L_{MCA2} in the Z direction. The radial width W_{VR5J} of the resistor region VR5_{J} is larger than the above-described widths W_{VRLU} and W_{VCUU}.

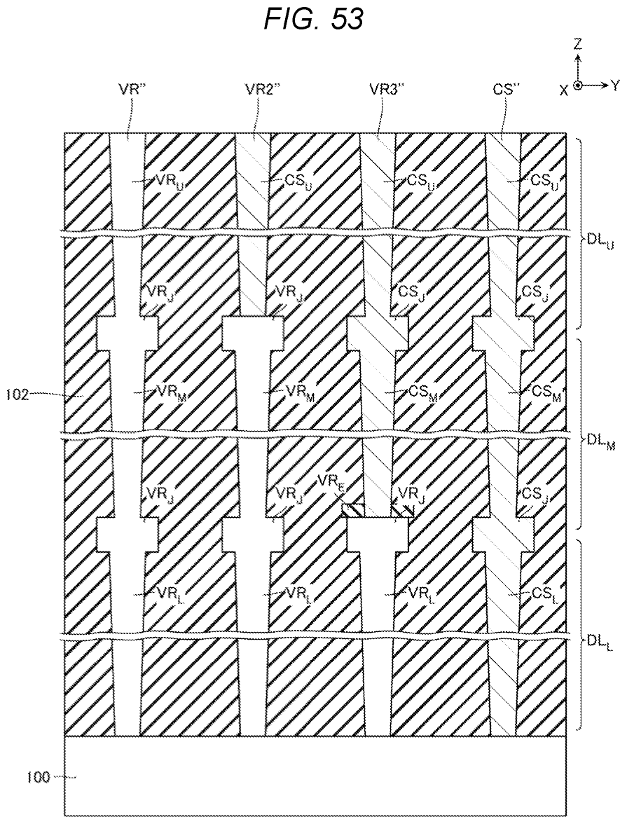

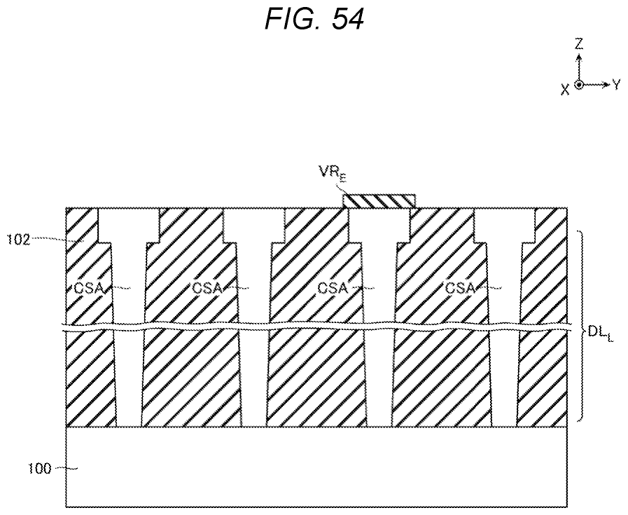

Next, a method of manufacturing the semiconductor storage device according to the fifth embodiment will be described with reference to FIGS. 51 and 52. FIGS. 51 and 52 are schematic cross-sectional views for illustrating the manufacturing method. FIGS. 51 and 52 show cross sections corresponding to FIG. 50.

In manufacturing the semiconductor storage device according to the present embodiment, first, among the processes in the method for manufacturing the semiconductor storage device according to the fourth embodiment, the processes described with reference to FIGS. 43 and 44 are performed.

Next, for example, as shown in FIG. 51, the contact holes UCH are covered by a resist 555.

Next, for example, as shown in FIG. 48, the amorphous silicon film 120A is removed from each memory hole LMH. The process is performed by, for example, a method such as wet etching.

Next, for example, among the processes in the method for manufacturing the semiconductor storage device according to the first embodiment, the processes described with reference to FIGS. 24 to 28 and the like are performed.

Next, for example, as shown in FIG. 52, an insulating layer VCA such as silicon oxide (SiO₂) is formed inside each contact hole UCH. In the process, for example, the resist 555 illustrated in FIG. 51 is removed. For example, the insulating layer VCA is formed by a method such as CVD and CMP.

Next, the via contact electrodes C4, CC, and the like described with reference to FIG. 36 are formed. When forming any of the via contact electrodes C4, CC, and the like, the insulating layer VCA formed inside each contact hole UCH is removed and the conductor region VC is formed here. As a result, the via resistors VR5 described with reference to FIG. 50 are formed.

After that, other wirings or the like is formed and the wafer is divided by dicing to form the semiconductor storage device according to the fifth embodiment.

According to the semiconductor storage device according to the fifth embodiment, it is possible to reduce the circuit area and implement resistance elements having suitable characteristics, similarly to the semiconductor storage device according to the fourth embodiment.

In the method for manufacturing a semiconductor storage device according to the fifth embodiment, the amorphous silicon film 120A used as a sacrificial film is used as the resistor region VR5_{L} and the resistor region VR5_{J} of the via resistor VR5, and the conductor region VC of the via resistor VR5 is formed at the same time as the other via contact electrodes. Therefore, the number of manufacturing processes can be reduced as compared with the manufacturing method of the semiconductor storage device according to the fourth embodiment.

### Sixth Embodiment

Next, a semiconductor storage device according to a sixth embodiment will be described.

The semiconductor storage device according to the sixth embodiment is basically configured in the same manner as the semiconductor storage device according to the fourth embodiment. However, the semiconductor storage device according to the sixth embodiment includes the via resistors VR5 (see FIG. 50) according to the fifth embodiment in addition to the via resistors VR4 (see FIG. 38) according to the fourth embodiment.

Next, a method of manufacturing the semiconductor storage device according to the sixth embodiment will be described.

In manufacturing the semiconductor storage device according to the present embodiment, first, among the processes in the method for manufacturing the semiconductor storage device according to the fourth embodiment, the processes described with reference to FIGS. 43 and 44 are performed.

Next, for example, as shown in FIG. 51, among the contact holes LCH and UCH, those provided at the positions corresponding to the via resistors VR5 are covered by the resist 555.

Next, for example, as shown in FIG. 45, an amorphous silicon film 120A is formed inside each memory hole UMH. For example, as shown in FIG. 46, the via resistors VR4 are formed inside the contact holes LCH and UCH. The process is performed by, for example, a method such as CVD.

Next, for example, as shown in FIG. 47, the upper surfaces of the via resistors VR4 are covered with the resist 455.

Next, among the processes in the method for manufacturing the semiconductor storage device according to the fourth embodiment, the processes described with reference to FIGS. 48 and 49 are performed.

Next, among the processes in the method for manufacturing the semiconductor storage device according to the first embodiment, the processes described with reference to FIGS. 24 to 28 and the like are performed.

After that, among the processes in the method for manufacturing the semiconductor storage device according to the fifth embodiment, the processes after the process described with reference to FIG. 52 are performed.

According to the semiconductor storage device according to the sixth embodiment, it is possible to reduce the circuit area and implement resistance elements having suitable characteristics, similarly to the semiconductor storage device according to the fourth embodiment.

According to the semiconductor storage device according to the sixth embodiment, it is possible to simultaneously adopt via resistors VR4 and VR5 having two resistance values. Thereby, the circuit area can be further reduced.

### Seventh Embodiment

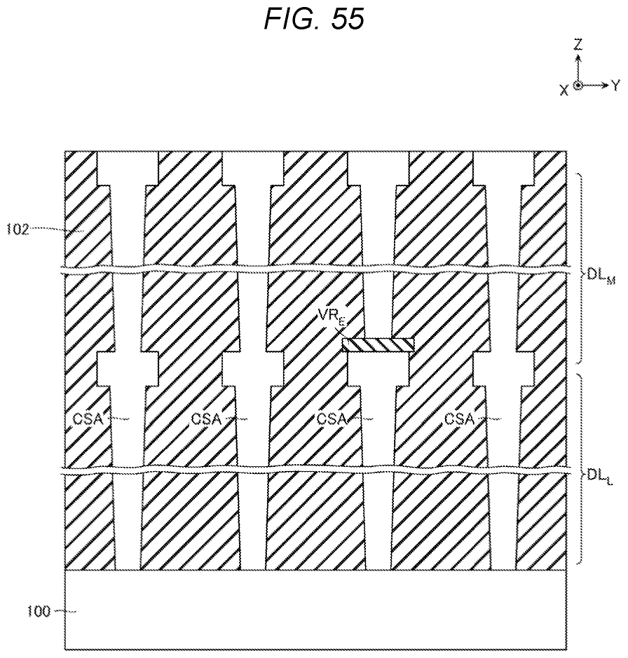

Next, a semiconductor storage device according to a seventh embodiment will be described with reference to FIG. 53. FIG. 53 is a schematic cross-sectional view of the semiconductor storage device according to the seventh embodiment.

The semiconductor storage device according to the seventh embodiment is basically configured in the same manner as the semiconductor storage device according to the first to third embodiments. However, the semiconductor storage device according to the seventh embodiment includes two device layers DL_{L} and DL_{U} arranged along the Z direction, and one device layer DL_{M} provided therebetween. The semiconductor storage device includes three types of via resistors VR″, VR2″, and VR3″ instead of the via resistors VR and VR2. The semiconductor storage device includes a via contact electrode CS″ instead of the via contact electrode CS.

The via resistor VR″ includes a resistor region VR_{L} in the device layer DL_{L}, a resistor region VR_{M} in the device layer DL_{M}, and a resistor region VR_{U} in the device layer DL_{U}. The via resistor VR″ includes a resistor region VR_{J} connected to the upper end of the resistor region VR_{L} and the lower end of the resistor region VR_{M}, and a resistor region VR_{J} connected to the upper end of the resistor region VR_{M} and the lower end of the resistor region VR_{U}. The resistor region VR_{M} is configured in the same manner as the resistor regions VR_{L} and VR_{U}.

The via resistor VR2″ includes a resistor region VR_{L} in the device layer DL_{L}, a resistor region VR_{M} in the device layer DL_{M}, and a conductor region CS_{U} in the device layer DL_{U}. The via resistor VR2″ includes a resistor region VR_{J} connected to the upper end of the resistor region VR_{L} and the lower end of the resistor region VR_{M}, and a resistor region VR_{J} connected to the upper end of the resistor region VR_{M} and the lower end of the conductor region CS_{U}.

The via resistor VR3″ includes a resistor region VR_{L} in the device layer DL_{L}, a conductor region CS_{M} in the device layer DL_{M}, and a conductor region CS_{U} in the device layer DL_{U}. The via resistor VR3″ includes a resistor region VR_{J} connected to the upper end of the resistor region VR_{L} and the lower end of the conductor region CS_{M}, and a conductor region CS_{J} connected to the upper end of the conductor region CS_{M} and the lower end of the conductor region CS_{U}. The conductor region CS_{M} is configured in the same manner as the conductor regions CS_{L} and CS_{U}. The via resistor VR3″ includes an insulating layer VR_{E} made of, for example, silicon nitride (Si₃N₄) provided on the upper surface of the resistor region VR_{J}. The insulating layer VR_{E} covers the outer peripheral surface of the lower end of the conductor region CS_{M}.

The via contact electrode CS″ includes a conductor region CS_{L} in the device layer DL_{L}, a conductor region CS_{M} in the device layer DL_{M}, and a conductor region CS_{U} in the device layer DL_{U}. The via contact electrode CS″ includes a conductor region CS_{J} connected to the upper end of the conductor region CS_{L} and the lower end of the conductor region CS_{M}, and a conductor region CS_{J} connected to the upper end of the conductor region CS_{M} and the lower end of the conductor region CS_{U}.

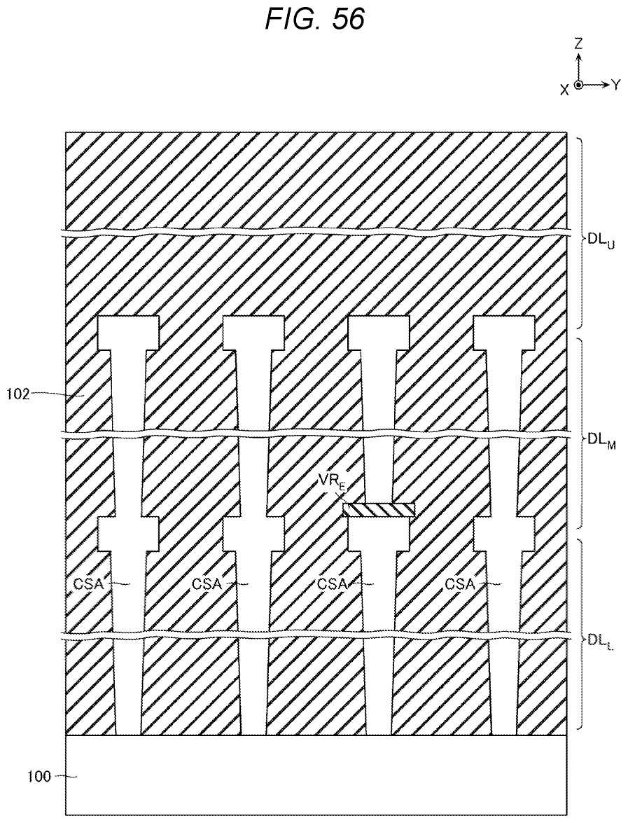

Next, a method of manufacturing the semiconductor storage device according to the seventh embodiment will be described with reference to FIGS. 54 to 63. FIGS. 54 to 63 are schematic cross-sectional views for illustrating the manufacturing method. FIGS. 54 to 63 show cross sections corresponding to FIG. 53.

In manufacturing the semiconductor storage device according to the present embodiment, first, among the processes in the method for manufacturing the semiconductor storage device according to the first embodiment, the processes up to the process described with reference to FIG. 19 are performed.

Next, as shown in FIG. 54, for example, among the plurality of amorphous silicon films CSA, the upper surface of the amorphous silicon film CSA corresponding to the via resistor VR3″ is covered with the insulating layer VR_{E}. The process is performed by, for example, a method such as CVD and wet etching.

Next, among the processes in the method for manufacturing the semiconductor storage device according to the first embodiment, the processes described with reference to FIGS. 20 and 21 are performed, and an amorphous silicon film 120A is formed inside each memory hole by a method such as CVD. Among the processes in the method for manufacturing the semiconductor storage device according to the first embodiment, the processes described with reference to FIGS. 11 to 13 are performed again.

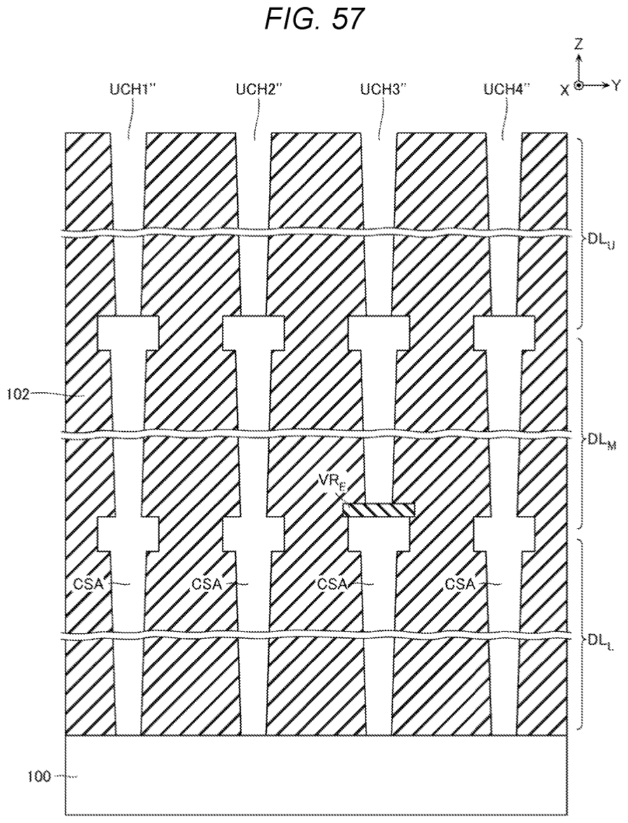

Next, among the processes in the method for manufacturing the semiconductor storage device according to the first embodiment, the processes described with reference to FIGS. 15 to 19 are re-executed. As a result, a structure as shown in FIG. 55 is formed.

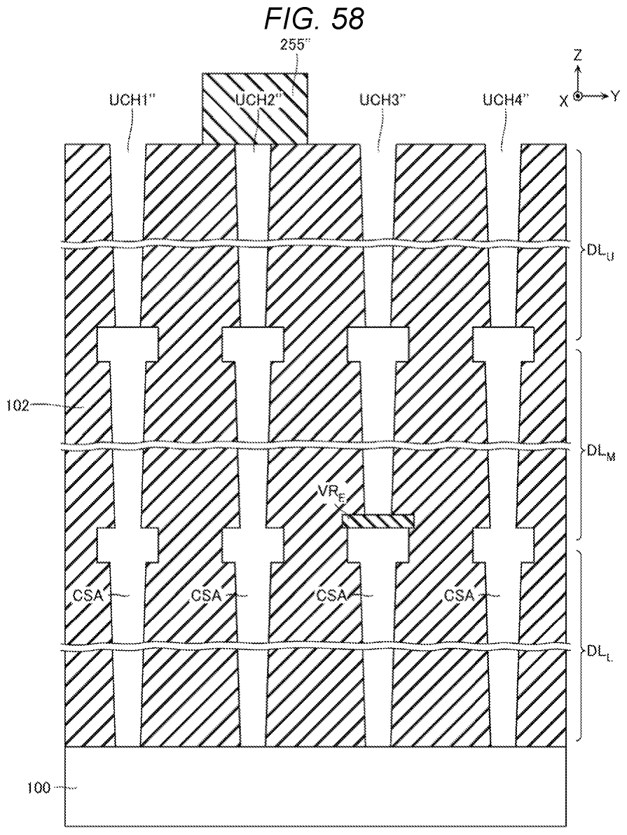

Next, among the processes in the method for manufacturing the semiconductor storage device according to the first embodiment, the processes described with reference to FIGS. 20 to 28 are performed. As a result, a structure as shown in FIG. 56 is formed.

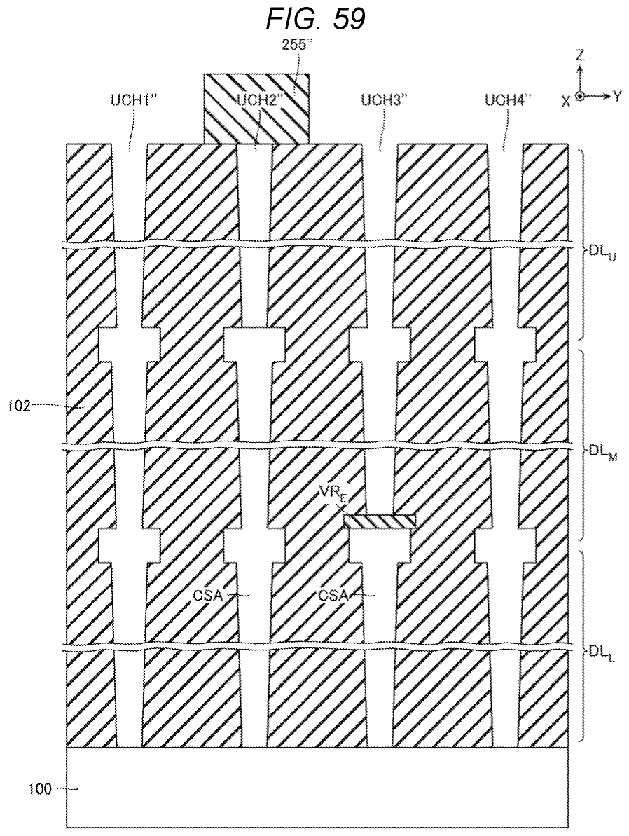

Next, as shown in FIG. 57, for example, a plurality of contact holes UCH are formed at positions corresponding to the via resistors VR″, VR2″, and VR3″, and the via contact electrode CS″. In FIG. 57, the contact holes UCH corresponding to the via resistors VR″, VR2″, and VR3″, and the via contact electrode CS″ are shown as the contact holes UCH1″, UCH2″, UCH3″, and UCH4″, respectively.

Next, for example, as shown in FIG. 58, the contact hole UCH2″ is covered by a resist 255″.

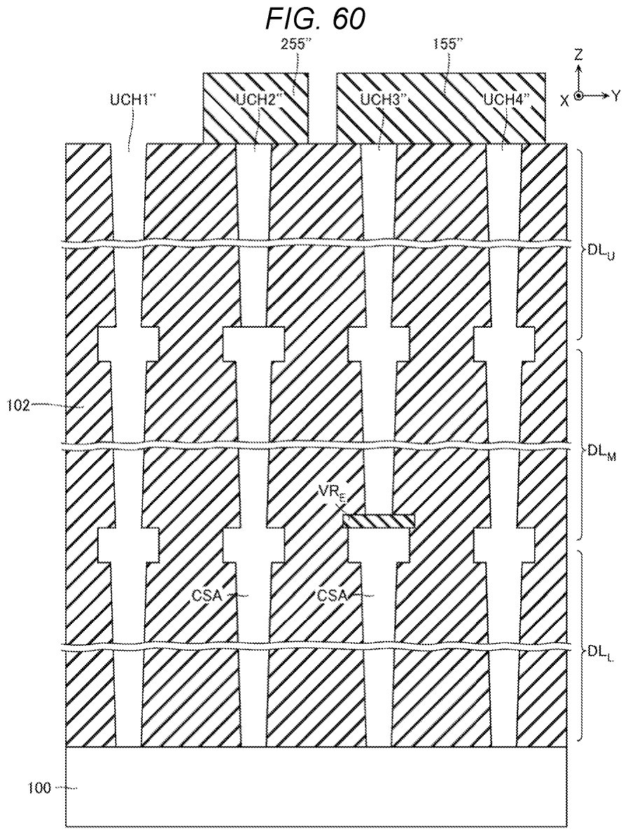

Next, as shown in FIG. 59, for example, the amorphous silicon film CSA is removed from the inside of each of the contact holes UCH1″, UCH3″, and UCH4″. Of the amorphous silicon film CSA provided inside the contact hole UCH3″, the portion provided below the insulating layer VR_{E} remains without being removed.

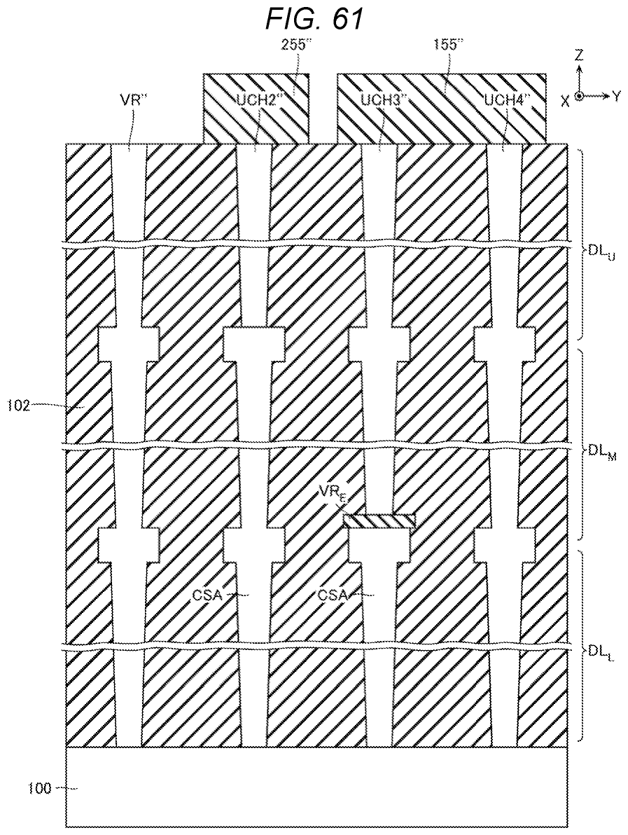

Next, for example, as shown in FIG. 60, the contact holes UCH3″ and UCH4″ are covered by a resist 155″.

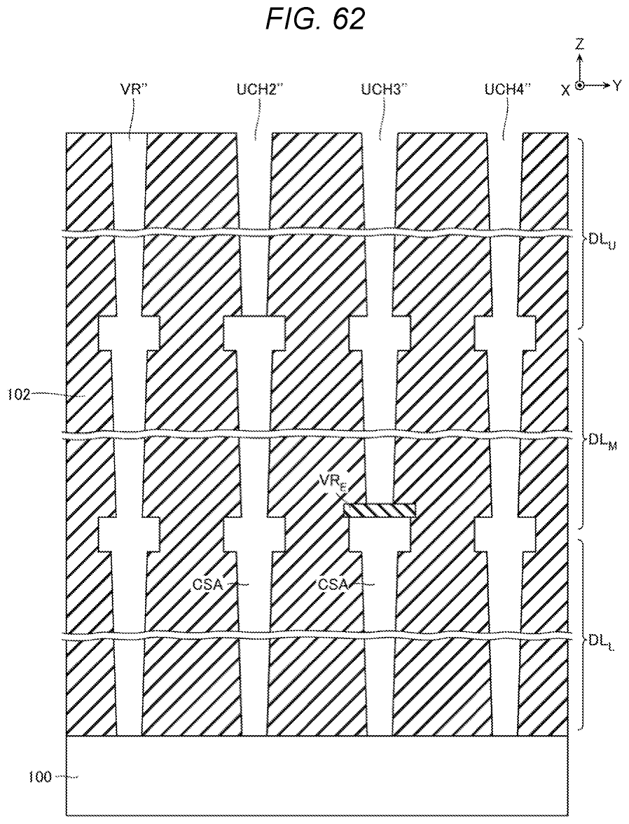

Next, as shown in FIG. 61, for example, the via resistor VR″ is formed inside the contact hole UCH1″.

Next, for example, as shown in FIG. 62, the resists 155″ and 255″ are removed.

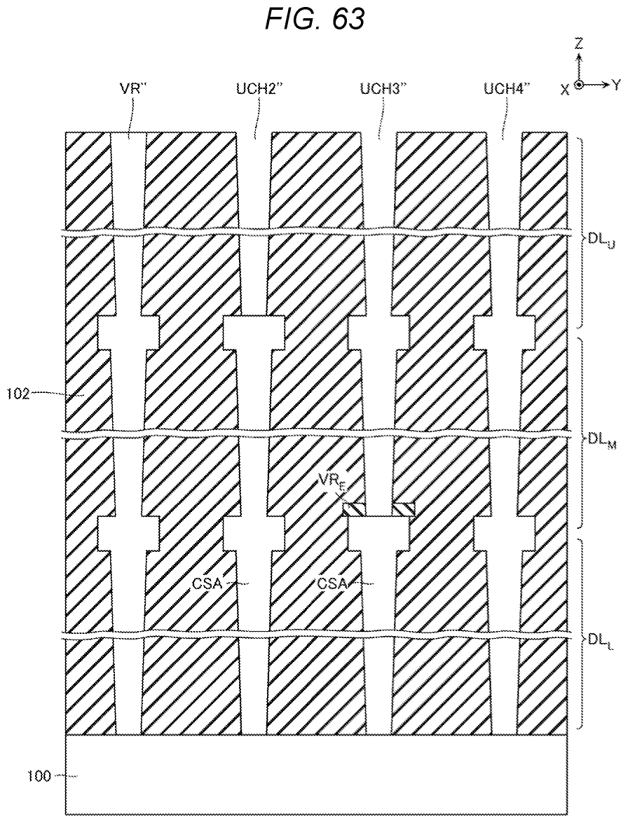

Next, as shown in FIG. 63, for example, at least a part of the insulating layer VR_{E} is removed to expose the amorphous silicon film CSA inside the contact hole UCH3″.

Next, as shown in FIG. 53, for example, the via resistor VR2″ and VR3″, and the via contact electrode CS are formed.

After that, the semiconductor storage device according to the seventh embodiment is formed by forming wirings and the like and dividing the wafer by dicing.

### Other Embodiments

The semiconductor storage devices according to the first to seventh embodiments have been described above.

However, the semiconductor storage devices according to the embodiments are merely examples, and specific configurations, operations, and the like can be appropriately adjusted.

For example, the via resistors VR, VR2, VR4, VR5, VR″, VR2″, and VR3″ according to the first to seventh embodiments include resistor regions VR_{J}, VR2_{J}, VR4_{J}, and VR5_{J}. However, it is also possible to omit the resistor regions VR_{J}, VR2_{J}, VR4_{J}, and VR5_{J} from the via resistors VR, VR2, VR4, VR5, VR″, VR2″, and VR3″. In such a case, for example, the processes described with reference to FIGS. 17 and 18 may be omitted.

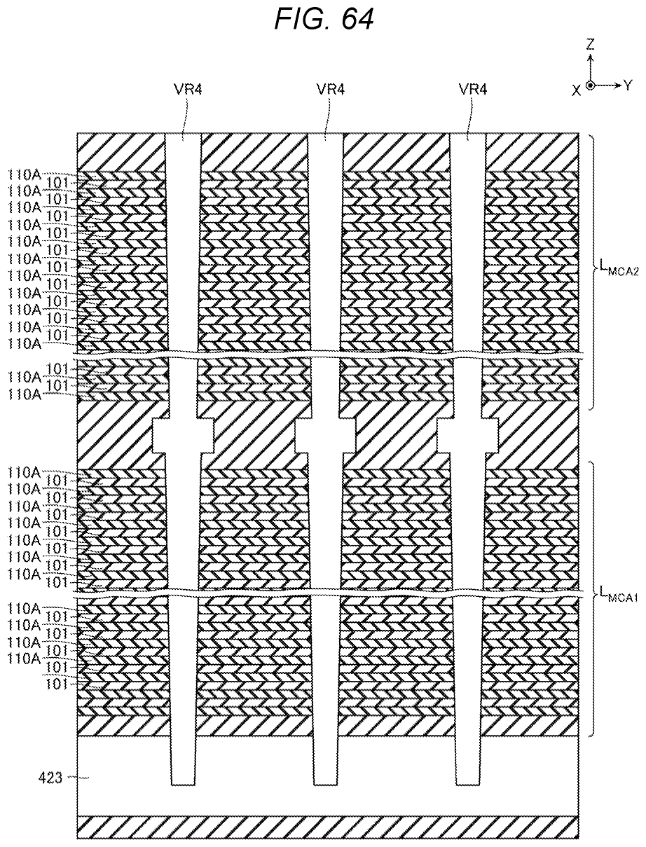

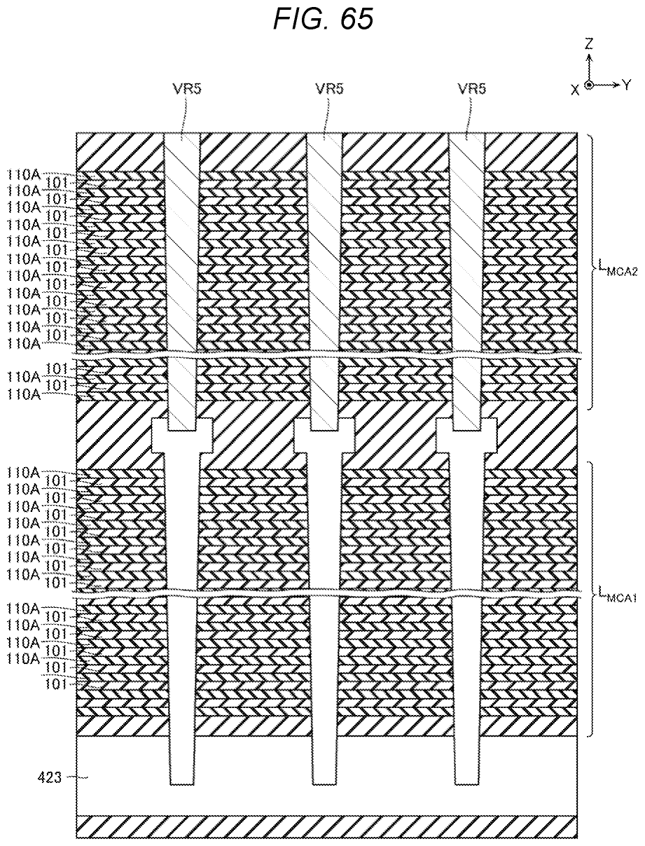

For example, the outer peripheral surfaces of the via resistors VR4 and VR5 according to the fourth to sixth embodiments are surrounded by the insulating layer 102. However, the outer peripheral surfaces of the via resistors VR4 and VR5 may be surrounded by the plurality of insulating layers 110A and the plurality of insulating layers 101, for example, as shown in FIGS. 64 and 65.

For example, the semiconductor storage device according to the seventh embodiment basically has the same configuration as the semiconductor storage device according to the first to third embodiments. The semiconductor storage device includes three device layers DL_{L}, DL_{M}, and DL_{U} arranged along the Z direction. As described above, the semiconductor storage device according to the first to third embodiments may include three or more device layers. Via resistors having three or more different resistance values may be provided. Similarly, the semiconductor storage device according to the fourth to sixth embodiments may include three or more memory cell array layers. Via resistors having three or more different resistance values may be provided.

The via resistors according to the first to seventh embodiments can be applied to various circuits.

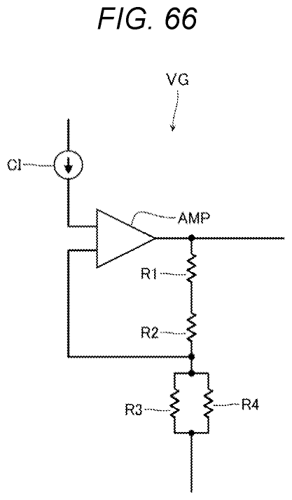

For example, FIG. 66 shows a part of a voltage generation circuit VG. The circuit shown in FIG. 66 includes a differential amplifier circuit AMP. The output terminal of a constant current circuit CI is connected to one input terminal of the differential amplifier circuit AMP. Two resistance elements R1 and R2 are connected in series between the other input terminal and the output terminal of the differential amplifier circuit AMP. The other input terminal of the differential amplifier circuit AMP is connected to another terminal via two resistance elements R3 and R4 connected in parallel. The via resistors according to the first to seventh embodiments may be used as, for example, these four resistance elements R1 to R4.

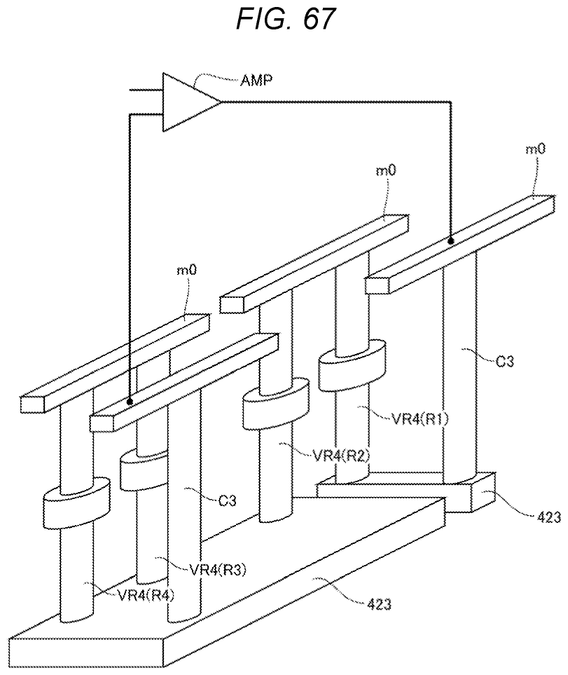

For example, FIG. 67 shows a configuration example in which the via resistors VR4 according to the fourth embodiment are used as the resistance elements R1 to R4 of FIG. 66. That is, the output terminal of the differential amplifier circuit AMP is electrically connected to the semiconductor layer 423 via the wiring m0 and the via contact electrode C3 made of, for example, tungsten (W). The semiconductor layer 423 is connected to the lower end of the via resistor VR4 that functions as the resistance element R1. The upper end of the via resistor VR4 is connected to the wiring m0. The wiring m0 is connected to the upper end of the via resistor VR4 that functions as the resistance element R2. The lower end of the via resistor VR4 is connected to the semiconductor layer 423. The semiconductor layer 423 is electrically connected to the input terminal of the differential amplifier circuit AMP via the via contact electrode C3 and the wiring m0. The semiconductor layer 423 is connected to the lower ends of two via resistors VR4 that function as resistance elements R3 and R4. The upper ends of the two via resistors VR4 are connected to the wiring m0. The wiring m0 is electrically connected to another component or the like.

[Others]

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a substrate;
a plurality of first conductive layers stacked on each other in a first direction intersecting a surface of the substrate;
a semiconductor layer extending in the first direction through the plurality of first conductive layers and facing each of first conductive layers in a second direction;
a gate insulating film between the semiconductor layer and the plurality of first conductive layers; and
a first resistance element on the substrate and extending in the first direction, wherein
one end of the first resistance element in the first direction is closer to the substrate than at least a part of the plurality of first conductive layers, and
the other end of the first resistance element in the first direction is farther from the substrate than the plurality of first conductive layers.

2. The semiconductor storage device according to claim 1, further comprising:
a plurality of second conductive layers stacked in the first direction and extending in the second direction, the plurality of second conductive layers being farther from the substrate in the first direction than the plurality of first conductive layers, and facing the semiconductor layer in the second direction, wherein
the other end of the first resistance element in the first direction is farther in the first direction from the substrate than the plurality of second conductive layers.

3. The semiconductor storage device according to claim 2, wherein
the first resistance element includes a first region and a second region arranged along the first direction in this order from the substrate,
one end of the first region in the first direction is closer in the first direction to the substrate than at least a part of the plurality of first conductive layers,
the other end of the first region in the first direction is farther in the first direction from the substrate than the plurality of first conductive layers,
one end of the second region in the first direction is closer in the first direction to the substrate than the plurality of second conductive layers, and
the other end of the second region in the first direction is farther in the first direction from the substrate than the plurality of second conductive layers.

4. The semiconductor storage device according to claim 3, wherein
a first width of said one end of the first region in the second direction is smaller than a second width of the other end of the first region in the second direction,
a third width of said one end of the second region in the second direction is smaller than a fourth width of the other end of the second region in the second direction, and
the third width is smaller than the second width.

5. The semiconductor storage device according to claim 4, wherein the first resistance element further includes a third region between the first and second regions and having a width in the second direction that is greater than the second and third widths.

6. The semiconductor storage device according to claim 3, wherein the first region includes a semiconductor material, and the second region includes either a semiconductor material or a conductor material.

7. The semiconductor storage device according to claim 3, further comprising:
a second resistance element extending along the first direction and including a third region and a fourth region arranged along the first direction in this order from the substrate, wherein
each of the first, second, and third regions includes a semiconductor material, and
the fourth region includes a conductor material.

8. The semiconductor storage device according to claim 7, wherein the fourth region is connected to the substrate via an insulating layer.

9. The semiconductor storage device according to claim 1, further comprising:
an electrode extending in the first direction between the plurality of first conductive layers and the first resistance element in a third direction intersecting the first and second directions.

10. The semiconductor storage device according to claim 9, wherein
the electrode includes a first region and a second region arranged along the first direction in this order from the substrate,
a fifth width of one end of the first region in the second direction is smaller than a sixth width of the other end of the first region in the second direction,
a seventh width of one end of the second region in the second direction is smaller than an eighth width of the other end of the second region in the second direction, and
the seventh width is smaller than the sixth width.

11. A memory die, comprising:
a substrate;
a plurality of memory cell arrays above the substrate and each memory cell array including:
a plurality of first conductive layers stacked in a first direction intersecting the substrate, the first conductive layers each extending in a second direction parallel to the substrate,
a semiconductor layer extending in the first direction through the plurality of first conductive layers and facing each of first conductive layers in the second direction, and
a gate insulating film between the semiconductor layer and the plurality of first conductive layers and; and
a peripheral circuit on the substrate and including a first resistance element extending in the first direction, wherein
one end of the first resistance element in the first direction is closer to the substrate than at least a part of the plurality of first conductive layers, and
the other end of the first resistance element in the first direction is farther from the substrate than the plurality of first conductive layers.

12. The memory die according to claim 11, wherein the peripheral circuit is between two of the memory cell arrays that are adjacent to each other.

13. The memory die according to claim 11, further comprising:
a first row decoder on the substrate between each of the two memory cell arrays and the peripheral circuit.

14. The memory die according to claim 13, further comprising:
a second row decoder on the substrate, wherein
one of the memory cell arrays is between the first row decoder and the second row decoder.

15. The memory die according to claim 11, wherein each of the memory cell arrays further includes:
a plurality of second conductive layers stacked in the first direction and extending along the second direction, the plurality of second conductive layers being farther from the substrate than the plurality of first conductive layers and facing the semiconductor layer in the second direction, wherein
the other end of the first resistance element in the first direction is farther in the first direction from the substrate than the plurality of second conductive layers.

16. A method of manufacturing a semiconductor device, comprising:
forming a plurality of first conductive layers above a first region of a substrate along a first direction intersecting the substrate so as to extend along a second direction parallel to the substrate;
forming a first insulating layer on a second region of the substrate;
forming a first hole penetrating the first conductive layers and reaching the substrate;
forming a second hole penetrating the first insulating layer and reaching the substrate;
forming a plurality of second conductive layers above the plurality of first conductive layers along the first direction so as to extend along the second direction;
forming a second insulating layer on the first insulating layer;
forming a third hole penetrating the second conductive layers and connected to the first hole;
forming a gate insulating film and a semiconductor layer in the first and third holes;
forming a fourth hole penetrating the second insulating layers and connected to the second hole; and
forming a first resistance element in the second and fourth holes.

17. The method according to claim 16, wherein
one end of the first resistance element in the first direction is closer in the first direction to the substrate than at least a part of the plurality of first conductive layers, and
the other end of the first resistance element in the first direction is farther in the first direction from the substrate than the plurality of first conductive layers.

18. The method according to claim 17, wherein the other end of the first resistance element in the first direction is farther in the first direction from the substrate than the plurality of second conductive layers.

19. The method according to claim 18, wherein
the first resistance element includes a first region and a second region arranged along the first direction in this order from the substrate,
one end of the first region in the first direction is closer in the first direction to the substrate than at least a part of the plurality of first conductive layers,
the other end of the first region in the first direction is farther in the first direction from the substrate than the plurality of first conductive layers,
one end of the second region in the first direction is closer in the first direction to the substrate than the plurality of second conductive layers, and
the other end of the second region in the first direction is farther in the first direction from the substrate than the plurality of second conductive layers.

20. The method according to claim 19, wherein
a first width of said one end of the first region in the second direction is smaller than a second width of the other end of the first region in the second direction,
a third width of said one end of the second region in the second direction is smaller than a fourth width of the other end of the second region in the second direction, and
the third width is smaller than the second width.
